(19) United States
(12) Patent Application Publication
(10) Pub. No.: US 2025/0107371 A1
(43) Pub. Date: Mar. 27, 2025

(54) DISPLAY DEVICE

(71) Applicant: Samsung Display Co., LTD., Yongin-si (KR)

(72) Inventors: Hyeongseok KIM, Yongin-si (KR); Heejean PARK, Yongin-si (KR); Sunhwa LEE, Yongin-si (KR); Mukyung JEON, Yongin-si (KR)

(21) Appl. No.: 18/893,653

(22) Filed: Sep. 23, 2024

(30) Foreign Application Priority Data
Sep. 26, 2023 (KR) 10-2023-0129557

(51) Int. Cl. H10K 59/131; H01L 25/075; H01L 25/16; H01L 33/62; H10K 77/10; H10K 102/00

(52) U.S. Cl. CPC H10K 59/131; H01L 25/167; H10H 20/857; H10K 77/111; H01L 25/0753; H10K 2102/311

(57) ABSTRACT

A display device in which first and second areas respectively on opposite sides of a display area are defined includes a plurality of first island portions arranged in the first area and spaced apart from each other, a plurality of first bridge portions extending to or connecting the plurality of first island portions adjacent to each other, and spaced apart from each other by a plurality of first openings, a plurality of second island portions arranged in the second area and spaced apart from each other, and a plurality of second bridge portions extending to or connecting the plurality of second island portions adjacent to each other, and spaced apart from each other by a plurality of second openings. The plurality of first bridge portions and the plurality of second bridge portions each have a serpentine shape, the plurality of first island portions and the plurality of second island portions are arranged symmetrically with respect to a center line between the first area and the second area, and the plurality of first bridge portions and the plurality of second bridge portions are arranged symmetrically with respect to the center line.

This application claims priority to Korean Patent Application No. 10-2023-0129557, filed on Sep. 26, 2023, and all the benefits accruing therefrom under 35 U.S.C. § 119, the content of which in its entirety is herein incorporated by reference.

### BACKGROUND

### 1. Field

Embodiments relate to a display device, e.g., a flexible display device.

### 2. Description of the Related Art

As display devices that display electrical signals visually are being developed, various display devices having excellent characteristics, such as reduction in thickness, weight, and power consumption, are being introduced. For example, flexible display devices that are foldable or rollable are being introduced. Recently, display devices with various structures, such as stretchable display devices capable of being deformed into various shapes, are being under research and development.

### SUMMARY

Embodiments include a display device, e.g., a flexible display device.

Additional features will be set forth in part in the description which follows and, in part, will be apparent from the description, or may be learned by practice of the presented embodiments of the disclosure.

In an embodiment of the disclosure, a display device in which a display area, and a first area and a second area respectively on opposite sides of the display area are defined includes first island portions arranged in the first area and spaced apart from each other, first bridge portions extending to or connecting the first island portions adjacent to each other, and spaced apart from each other by first openings, second island portions arranged in the second area and spaced apart from each other, and second bridge portions extending to or connecting the second island portions adjacent to each other, and spaced apart from each other by second openings, where the first bridge portions and the second bridge portions each have a serpentine shape, the first island portions and the second island portions are arranged symmetrically with respect to a center line between the first area and the second area, and the first bridge portions and the second bridge portions are arranged symmetrically with respect to the center line.

In an embodiment, the first island portions may include first driver units, the second island portions may include second driver units, and the first driver units and the second driver units may be disposed symmetrically with respect to the center line.

In an embodiment, the first bridge portions may include first wirings, the second bridge portions may include second wirings, and the first wirings and the second wirings may be disposed symmetrically with respect to the center line.

In an embodiment, the display device may further include a third area above the display area and between the first area and the second area, third island portions arranged in the third area and spaced apart from each other, and third bridge portions extending to or connecting the third island portions adjacent to each other and spaced apart from each other by third openings, where the third bridge portions may each have a serpentine shape.

In an embodiment, the third bridge portions may have a same shape as that of the first bridge portions.

In an embodiment, the third bridge portions may have a same shape as that of the second bridge portions.

In an embodiment, the display device may further include main island portions arranged in the display area and spaced apart from each other, and main bridge portions extending to the main island portions adjacent to each other, and spaced apart from each other by main openings, where the main bridge portions each have a serpentine shape.

In an embodiment, the main island portions and the first island portions may be disposed in a matrix form, and the main island portions arranged in one row may correspond to the first island portions arranged in a plurality of rows.

In an embodiment, the display device may further include a fourth area between the first area and the display area, and fourth bridge portions arranged in the fourth area and extending to the first island portions and the main island portions adjacent to each other.

In an embodiment, the display area may include a first display area and a second display area with the center line therebetween, the main island portions of the first display area and the main island portions of the second display area may be disposed symmetrically with respect to the center line, and the main bridge portions of the first display area and the main bridge portions of the second display area may be disposed symmetrically with respect to the center line.

In an embodiment, the third area may include a first sub-area and a second sub-area with the center line therebetween, the third island portions of the first sub-area and the third island portions of the second sub-area may be disposed symmetrically with respect to the center line, and the third bridge portions of the first sub-area and the third bridge portions of the second sub-area may be disposed symmetrically with respect to the center line.

In an embodiment, the display device may further include a first central area between the first display area and the second display area, and a second central area between the first sub-area and the second sub-area, where the center line may pass through the first central area and the second central area.

In an embodiment, openings corresponding to the first central area and the second central area may be defined in the first central area and the second central area.

In an embodiment, the display device may further include first central bridge portions arranged in the first central area and extending to the main island portions of the first display area and the main island portions of the second display area, the main island portions of the first display area and the main island portions of the second display area being adjacent to each other.

In an embodiment, the display device may further include second central bridge portions arranged in the second central area and extending to the third island portions of the first sub-area and the third island portions of the second sub-area, the third island portions of the first sub-area and the third island portions of the second sub-area being adjacent to each other.

In an embodiment, an opening corresponding to the second central area may be defined in the second central area.

In an embodiment, the display device may further include second central bridge portions arranged in the second central area and extending to the third island portions of the first sub-area and the third island portions of the second sub-area, the third island portions of the first sub-area and the third island portions of the second sub-area being adjacent to each other, where an opening corresponding to the first central area may be defined in the first central area.

In an embodiment, a width of each of the second central bridge portions may be greater than a width of each of the first central bridge portions.

In an embodiment, the first central bridge portions may each have a serpentine shape.

In an embodiment, the first central bridge portions may each have a straight-line shape.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a perspective view schematically illustrating an embodiment of a display device;

FIGS. 2A and 2B are perspective views illustrating the display device of FIG. 1, which is stretched in a first direction;

FIG. 2C is a perspective view illustrating the display device of FIG. 1, which is stretched in a second direction;

FIG. 2D is a perspective view illustrating the display device of FIG. 1, which is stretched in the first and second directions;

FIG. 2E is a perspective view illustrating the display device of FIG. 1, which is stretched in a third direction;

FIGS. 3A and 3B are plan views schematically illustrating an embodiment of a display device;

FIG. 4A is an enlarged plan view of an embodiment of region IV of FIG. 3A as a portion of a display device;

FIG. 4B is an enlarged plan view of an embodiment of region IV of FIG. 3A as a portion of a display device;

FIG. 4C is an enlarged plan view of an embodiment of region IV of FIG. 3A as a portion of a display device;

FIG. 5 is a cross-sectional view schematically illustrating an embodiment of a first island portion and a first bridge portion, which are arranged in a display area of a display device;

FIGS. 6A to 6C are equivalent circuit diagrams of a sub-pixel of a display device;

FIGS. 7A and 7B are cross-sectional views schematically illustrating an embodiment of a light-emitting element of a display device;

FIG. 8A is a diagram schematically illustrating an embodiment of a partial area included in a display device;

FIG. 8B is an enlarged plan view of an embodiment of region V of FIG. 3B as a portion of a display device;

FIG. 9 is an enlarged plan view of an embodiment of regions A and B of FIG. 8B as a portion of a display device;

FIG. 10 is an enlarged plan view of an embodiment of region V of FIG. 3B as a portion of a display device;

FIG. 11 is an enlarged plan view of another embodiment of region V of FIG. 3B as a portion of a display device;

FIG. 12A is a diagram schematically illustrating an embodiment of a partial area included in a display device;

FIG. 12B is an enlarged plan view of an embodiment of region V of FIG. 3B as a portion of a display device;

FIG. 13 is an enlarged plan view of an embodiment of regions C and D of FIG. 12B as a portion of a display device;

FIGS. 14A to 14E are enlarged plan views of another embodiment of region E of FIG. 12B as a portion of a display device;

FIGS. 15A to 15D are enlarged plan views of another embodiment of region E of FIG. 12B as a portion of a display device; and

FIGS. 16A to 16G are perspective views schematically illustrating embodiments of an electronic apparatus including the display device.

### DETAILED DESCRIPTION

Reference will now be made in detail to embodiments, embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the description allows for various changes and numerous embodiments, illustrative embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals.

It will be understood that although the terms “first,” “second,” etc. may be used herein to describe various elements, these elements should not be limited by these terms. These terms are only used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

It will be further understood that, when a layer, region, or element is referred to as being “on” another layer, region, or element, it may be directly or indirectly on the other layer, region, or element. That is, for example, intervening layers, regions, or elements may be present.

Also, sizes of elements in the drawings may be exaggerated or reduced for convenience of explanation. For example, because sizes and thicknesses of elements in the drawings are arbitrarily illustrated for convenience of explanation, the disclosure is not limited thereto.

When an illustrative embodiment may be implemented differently, a specific process order may be performed differently from the described order. For example, two consecutively described processes may be performed substantially at the same time or performed in an order opposite to the described order.

Throughout the disclosure, the expression “A and/or B” indicates only A, only B, or both A and B. In addition, the expression “at least one of A or B” indicates only A, only B, or both A and B.

It will be further understood that when layers, regions, or elements are referred to as being connected to each other, they may be directly connected to each other or indirectly connected to each other with intervening layers, regions, or elements therebetween. For example, when layers, regions, or elements are referred to as being electrically connected to each other, they may be directly electrically connected to each other or indirectly electrically connected to each other with intervening layers, regions, or elements therebetween.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

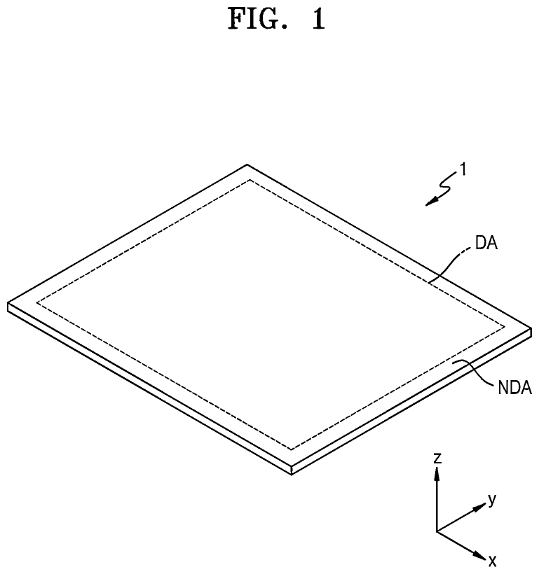

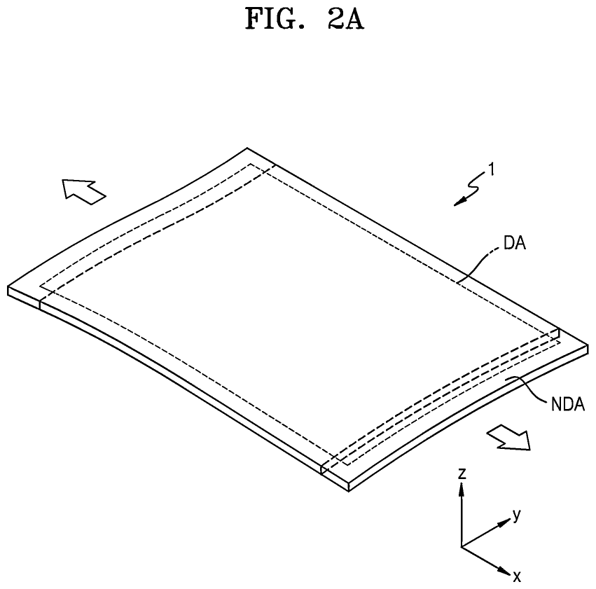

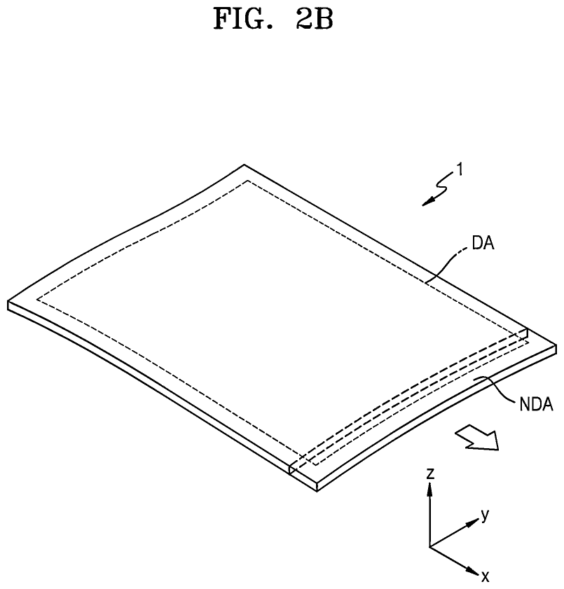

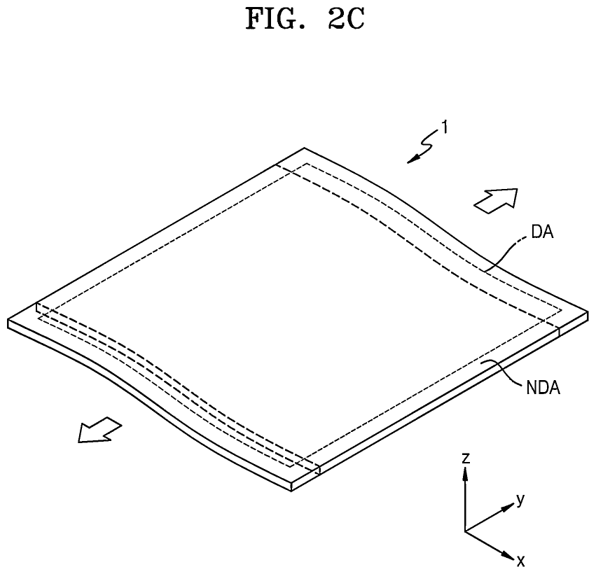

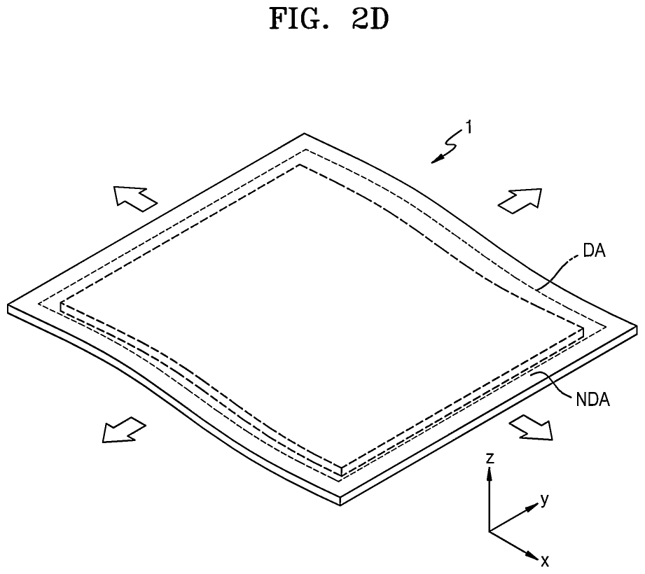

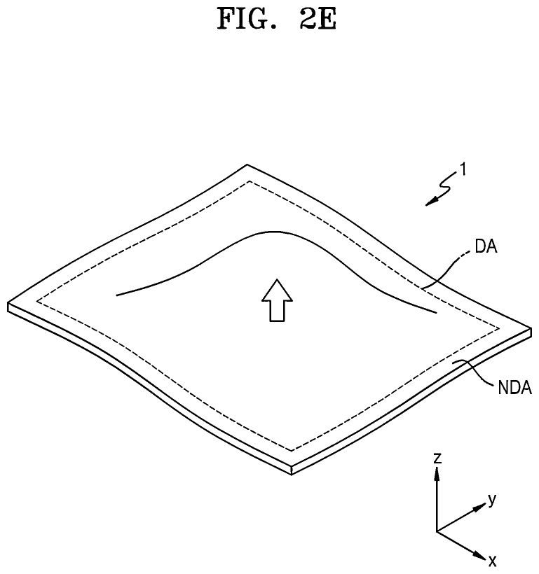

FIG. 1 is a perspective view schematically illustrating an embodiment of a display device 1. FIGS. 2A and 2B are perspective views illustrating the display device 1 of FIG. 1, which is stretched in a first direction. FIG. 2C is a perspective view illustrating the display device 1 of FIG. 1, which is stretched in a second direction. FIG. 2D is a perspective view illustrating the display device 1 of FIG. 1, which is stretched in the first and second directions. FIG. 2E is a perspective view illustrating the display device 1 of FIG. 1, which is stretched in a third direction.

Referring to FIG. 1, the display device 1 may include a display area DA and a non-display area NDA. The display area DA may include a plurality of pixels. The display device 1 may provide a predetermined image by light emitted from the pixels. The non-display area NDA may be outside the display area DA. The non-display area NDA is an area in which pixels are not disposed, and may completely surround the display area DA.

The display device 1 may be stretched or contracted in various directions. The display device 1 may be stretched in the first direction (e.g., the +x direction and/or the −x direction) by external force applied by an external object or a user. In an embodiment, as illustrated in FIGS. 2A and 2B, the display area DA and/or the non-display area NDA of the display device 1 may be stretched in the first direction (e.g., the +x direction and/or the −x direction). In an embodiment, as illustrated in FIG. 2A, the display device 1 may be stretched in the +x direction and the −x direction, or as illustrated in FIG. 2B, the display device 1 may be stretched in the +x direction while one side of the display device 1 is fixed, for example.

The display device 1 may be stretched in the second direction (e.g., the +y direction and/or the −y direction) by external force applied by an external object or a user. In an embodiment, as illustrated in FIG. 2C, the display area DA and/or the non-display area NDA of the display device 1 may be stretched in the +y direction and the −y direction. In another embodiment, the display device 1 may be stretched in the +y direction or the −y direction while one side of the display device 1 is fixed.

The display device 1 may be stretched in a plurality of directions, e.g., the first direction (e.g., the +x direction and/or the −x direction) and the second direction (e.g., the +y direction and/or the −y direction) by external force applied by an external object or a part of a person's body. As illustrated in FIG. 2D, the display area DA and/or the non-display area NDA of the display device 1 may be stretched in the +x direction and the ty direction.

The display device 1 may be stretched in the third direction (e.g., the +z direction or the −z direction) by external force applied by an external object or a part of a person's body. In an embodiment, FIG. 2E illustrates that a portion of the display device 1, e.g., a portion of the display area DA protrudes in the +z direction. In another embodiment, a portion of the display device 1, e.g., a portion of the display area DA may protrude in the −z direction (or may be recessed in the +z direction).

FIGS. 2A to 2E illustrate that the display device 1 is stretched in the first direction, the second direction, and/or the third direction, but the disclosure is not limited thereto. In another embodiment, the display device 1 may be deformed into various irregular shapes. In an embodiment, the display device 1 may be bent or twisted with respect to two or more axes, for example.

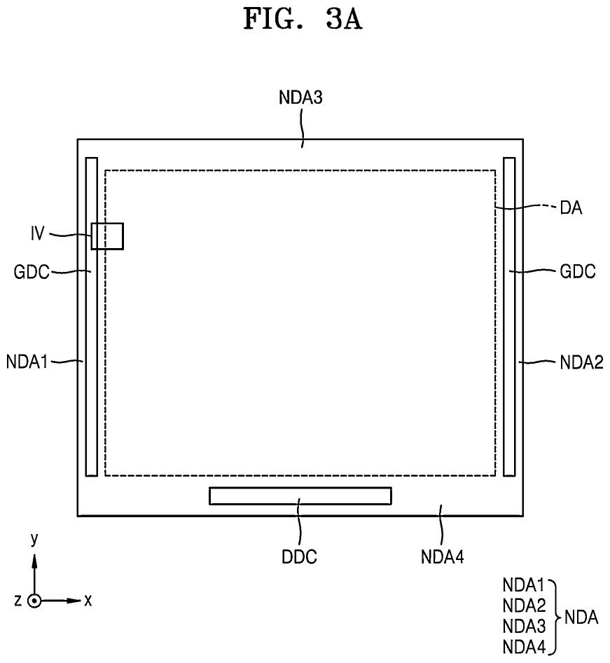

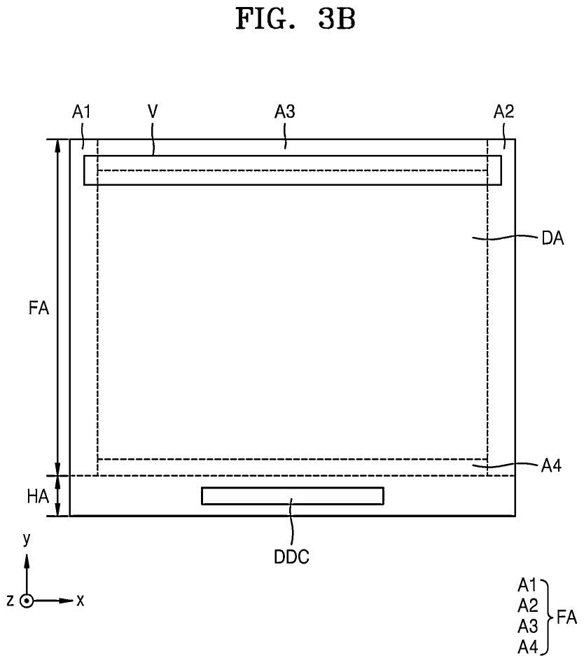

FIG. 3A is a plan view schematically illustrating an embodiment of a display device 1.

A plurality of pixels may be disposed in a display area DA of the display device 1. The pixels may each include sub-pixels which emit pieces of light of different colors. Light-emitting elements corresponding to the sub-pixels may be disposed in the display area DA. A circuit which provides electrical signals to the light-emitting elements arranged in the display area DA and transistors electrically connected to the light-emitting elements may be disposed in the non-display area NDA surrounding the display area DA. Gate driving circuits GDC may be respectively disposed in a first non-display area NDA1 and a second non-display area NDA2 disposed on opposite sides of the display area DA. The gate driving circuit GDC may include drivers which provide electrical signals to gate electrodes of the transistors electrically connected to the light-emitting elements. Although FIG. 3A illustrates that gate driving circuits GDC are respectively disposed in the first non-display area NDA1 and the second non-display area NDA2, the disclosure is not limited thereto. In another embodiment, the gate driving circuit GDC may be disposed in either the first non-display area NDA1 or the second non-display area NDA2.

A data driving circuit DDC may be disposed in a third non-display area NDA3 and/or a fourth non-display area NDA4 extending from the first non-display area NDA1 and the second non-display area NDA2. In an embodiment, FIG. 3A illustrates that the data driving circuit DDC is disposed in the fourth non-display area NDA4. In another embodiment, the data driving circuits DDC may be respectively disposed in the third non-display area NDA3 and the fourth non-display area NDA4.

Although FIG. 3A illustrates that the data driving circuit DDC is disposed in the fourth non-display area NDA4 of the display device 1, the disclosure is not limited thereto. In another embodiment, the display device 1 may further include a flexible circuit board (not shown) electrically connected through a terminal portion (not shown) disposed in the fourth non-display area NDA4, and the data driving circuit DDC may be disposed on the flexible circuit board.

In some embodiments, the elongation rate of the non-display area NDA may be less than or equal to the elongation rate of the display area DA. In an embodiment, the elongation rate of the non-display area NDA may be different for each area. In an embodiment, the first non-display area NDA1, the second non-display area NDA2, and the third non-display area NDA3 may have substantially the same elongation rate, but the elongation rate of the fourth non-display area NDA4 may be less than the elongation rate of each of the first non-display area NDA1, the second non-display area NDA2, and the third non-display area NDA3, for example.

FIG. 3B is a plan view schematically illustrating an embodiment of a display device 1.

Referring to FIG. 3B, the display device 1 may define a flexible area FA and a hard area HA. The flexible area FA may refer to a flexible area of the display device 1 with a relatively high elongation rate, and the hard area HA may refer to a hard area of the display device 1 with a relatively low elongation rate.

The flexible area FA may be a flexible area that is easily bendable, foldable, or stretchable. The flexible area FA may be easily stretched or contracted, compared to the hard area HA. In an embodiment, a plurality of openings (not shown) may be defined in the flexible area FA. The openings may be an area in which elements of the display device 1 are not disposed. Accordingly, the display device 1 may be easily stretched and/or contracted in various directions.

The hard area HA may be a rigid area that is not easily bendable. In an embodiment, the hard area HA may be an area in which an opening (not shown) is not disposed. Accordingly, the hard area may be an area in which stretching and/or contract are not easy.

In an embodiment, a data driving circuit DDC may be disposed in the hard area HA. In another embodiment, the display device 1 may further include a flexible circuit board (not shown) electrically connected through a terminal portion (not shown) disposed in the hard area HA, and the data driving circuit DDC may be disposed on the flexible circuit board.

The flexible area FA may include a display area DA and at least a portion of a non-display area (refer to NDA of FIG. 3A) surrounding the display area DA. The hard area HA may include a portion of the non-display area NDA. In an embodiment, the flexible area FA may include the display area DA, first to third non-display areas NDA1, NDA2, and NDA3, and a portion of a fourth non-display area NDA4, for example. The hard area HA may include a portion of the fourth non-display area NDA4.

The flexible area FA may include the display area DA and first to fourth peripheral areas A1, A2, A3, and A4 surrounding the display area DA. In an embodiment, the first peripheral area A1 may be disposed on the left side (e.g., the −x direction) of the display area DA, and the second peripheral area A2 may be disposed on the right side (e.g., the +x direction) of the display area DA, for example. The third peripheral area A3 may be disposed above the display area DA (e.g., the +y direction), and the fourth peripheral area A4 may be disposed below the display area DA (e.g., the −y direction). The third peripheral area A3 and the fourth peripheral area A4 may be between the first peripheral area A1 and the second peripheral area A2 in the +x direction and the −x direction.

The first peripheral area A1 and the second peripheral area A2 may correspond to the first non-display area NDA1 and the second non-display area NDA2 of the non-display area NDA, and gate driving circuits (refer to GDC of FIG. 3A) may be respectively disposed in the first peripheral area A1 and the second peripheral area A2.

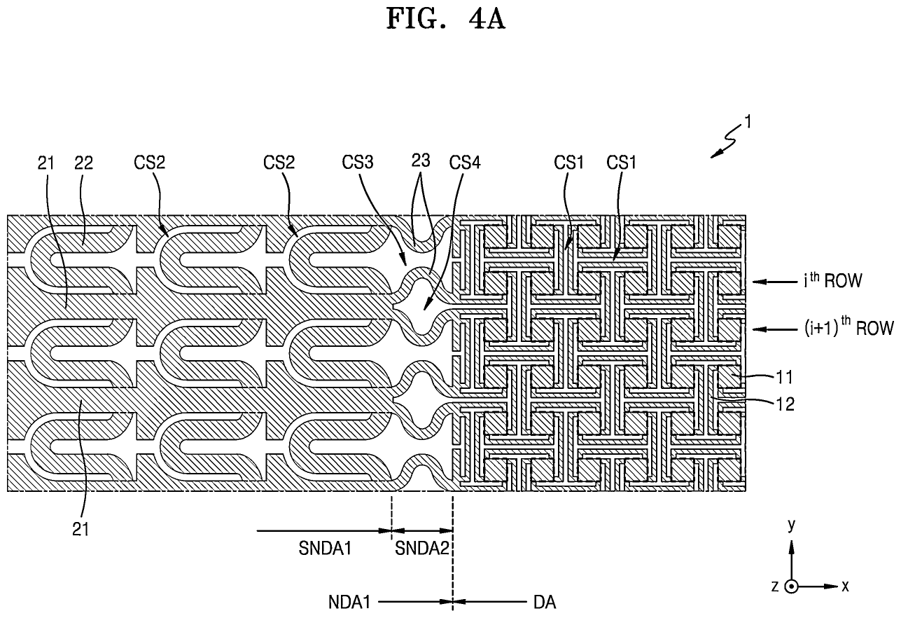

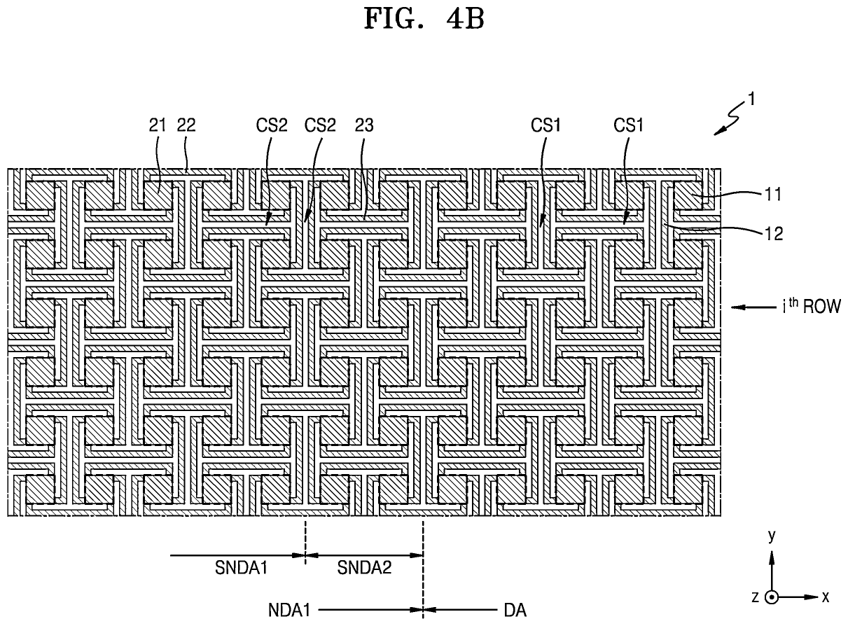

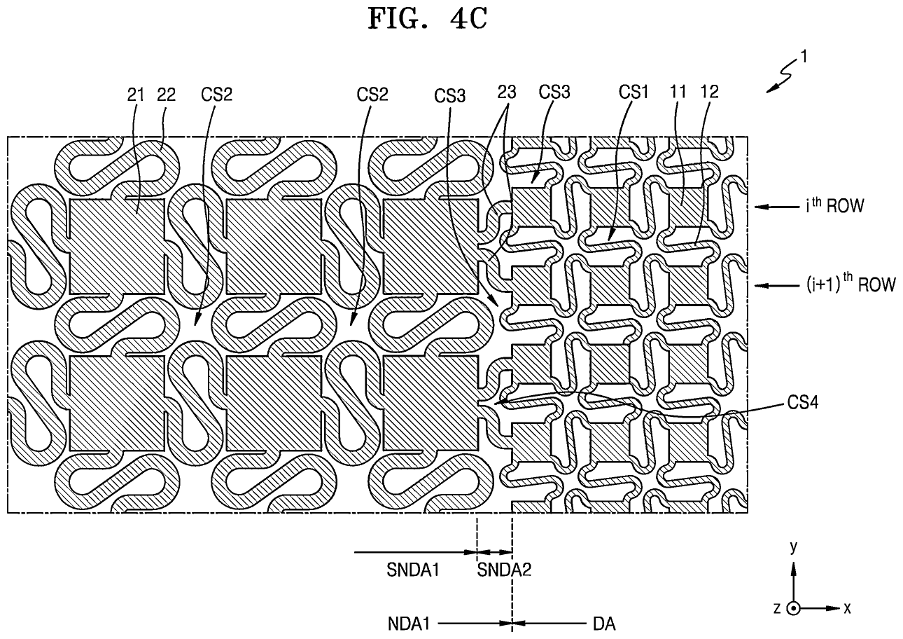

FIG. 4A is an enlarged plan view of an embodiment of region IV of FIG. 3A as a portion of the display device 1.

Referring to FIG. 4A, the display device 1 may include first island portions 11 spaced apart from each other in the first direction (e.g., the +x direction or the −x direction) and the second direction (e.g., the +y direction or the −y direction) in the display area DA, and first bridge portions 12 extending from the adjacent first island portions 11 to each other.

Each of the first island portions 11 may be extended to a plurality of first bridge portions 12. In an embodiment, each of the first island portions 11 may be extended to four first bridge portions 12, for example. The two first bridge portions 12 may be respectively disposed on opposite sides of the first island portion 11 in the first direction (e.g., the +x direction or the −x direction), and the remaining two first bridge portions 12 may be respectively disposed on opposite sides of the first island portion 11 in the second direction (e.g., the +y direction or the −y direction). In an embodiment, the four first bridge portions 12 may be respectively extended to four sides of the first island portion 11. The four first bridge portions 12 may be respectively adjacent to corners of the first island portion 11.

The first bridge portions 12 may be spaced apart from each other by a first opening CS1 between the first bridge portions 12. In an embodiment, a first opening CS1 having an approximately H shape and a first opening CS1 having an approximately I-shape obtained by rotating the H-shape by 90 degrees may be alternately and repeatedly disposed in the first direction (e.g., the +x direction or the −x direction) and the second direction (e.g., the +y direction or the −y direction). Both end portions of each of the first bridge portions 12 may be respectively extended to the adjacent first island portions 11, and one side of each of the first bridge portions 12 may be spaced apart from one side of the adjacent first island portion 11 and/or one side of another first bridge portion 12 by the first opening CS1.

The display device 1 may include second island portions 21 spaced apart from each other and second bridge portions 22 extended to the adjacent second island portions 21 to each other in the non-display area, e.g., the first non-display area NDA1 illustrated in FIG. 4A.

Each of the second island portions 21 may extend in the first direction (e.g., the +x direction or the −x direction). The second island portions 21 may be spaced apart from each other in the second direction (e.g., the +y direction or the −y direction) crossing the first direction (e.g., the +x direction or the −x direction). The second island portions 21 may include drivers of the gate driving circuit (refer to GDC of FIG. 3A) described with reference to FIG. 3A.

The second bridge portion 22 may have a serpentine shape. The length of the second bridge portion 22 may be greater than the shortest distance between the second island portions 21 adjacent to each other in the second direction (e.g., the +y direction or the −y direction). In an embodiment, the second bridge portion 22 may have an approximately omega (Ω) shape that is convex in the first direction (e.g., the +x direction or the −x direction). The second bridge portions 22 may be between the second island portions 21 adjacent to each other and may be spaced apart from each other.

The second bridge portions 22 between the second island portions 21 adjacent to each other may be spaced apart from each other by the second opening CS2. The second openings CS2 and the second bridge portions 22 may be alternately disposed in the first direction (e.g., the +x direction or the −x direction) between the second island portions 21 adjacent to each other. The second openings CS2 may have the same shape. Both end portions of each of the second bridge portions 22 may be extended to the adjacent second island portions 21, and one side of each of the second bridge portions 22 may be spaced apart from one side of the adjacent second island portion 21 and/or one side of another second bridge portion 22 by the second opening CS2.

One second island portion 21 disposed in the first non-display area NDA1 may correspond to a plurality of rows of first island portions 11 disposed in the display area DA1. In an embodiment, one second island portion 21 disposed in the first non-display area NDA1 may correspond to first island portions 11 disposed in an i^{th} row and first island portions 11 disposed in an (i+1)^{th} row in the display area DA (where i is a positive number greater than 0), for example. Although FIG. 4A illustrates that one second island portion 21 corresponds to two rows of the first island portions 11, the disclosure is not limited thereto. In another embodiment, one second island portion 21 disposed in the first non-display area NDA1 may correspond to n rows of the first island portions 11 disposed in the display area DA1 (where n is a positive number greater than or equal to 3).

The non-display area, e.g., the first non-display area NDA1 may include a first sub-non-display area SNDA1 in which the second island portions 21 and the second bridge portions 22 are arranged, and a second sub-non-display area SNDA2 between the first sub-non-display area SNDA1 and the display area DA. Third bridge portions 23 may be disposed in the second sub-non-display area SNDA2 and extend to the display area DA and the first sub-non-display area SNDA1. One end portion of the third bridge portion 23 may be extended to the second island portion 21 and/or the second bridge portion 22, and an opposite end portion of the third bridge portion 23 may be extended to the first island portion 11 and/or the first bridge portion 12.

The third bridge portion 23 may have a serpentine shape. In an embodiment, the shape of the third bridge portion 23 may be different from the shape of the first bridge portion 12 and the shape of the second bridge portion 22. In an embodiment, as illustrated in FIG. 4A, the third bridge portion 23 may have an approximately omega (Ω) shape that is convex in the second direction (e.g., the +y direction or the −y direction). The third bridge portions 23 may have a symmetrical structure in which one of the adjacent third bridge portions 23 disposed in the second direction (e.g., the +y direction or the −y direction) is convex in the +y direction and another thereof is convex in the −y direction. The third openings CS3 and the fourth openings CS4 having different shapes from each other may be repeated between the third bridge portions 23. The width of the third bridge portion 23 may be different from the width of the first bridge portion 12 and the width of the second bridge portion 22. In an embodiment, the width of the third bridge portion 23 may be greater than the width of the first bridge portion 12 and less than the width of the second bridge portion 22.

FIG. 4A illustrates that the second island portion 21 and the second bridge portion 22 in the non-display area, e.g., the first non-display area NDA1, have different shapes from the first island portion 11 and the first bridge portion 12 in the display area DA. In another embodiment, the second island portion 21 and the second bridge portion 22 in the non-display area may have the same shape as that of the first island portion 11 and the first bridge portion 12 in the display area DA, respectively.

FIG. 4B is an enlarged plan view of an embodiment of region IV of FIG. 3A as a portion of the display device 1.

Referring to FIG. 4B, the display device 1 may include first island portions 11 spaced apart from each other in a display area DA, and first bridge portions 12 spaced apart from each other by first openings CS1 and connecting the adjacent first island portions 11 to each other. The structure of the display area DA in FIG. 4B may be the same as the structure of the display area DA described with reference to FIG. 4A.

The display device 1 may include second island portions 21 and second bridge portions 22 disposed in a non-display area, e.g., a first non-display area NDA1. In an embodiment, the second island portions 21 and the second bridge portions 22 may have substantially the same shape as that of the first island portions 11 and the first bridge portions 12, respectively.

The second island portions 21 may be spaced apart from each other in the first direction (e.g., the +x direction or the −x direction) and the second direction (e.g., the +y direction or the −y direction) in the non-display area, e.g., the first non-display area NDA1. The second bridge portions 22 may each connect the adjacent second island portions 21 to each other. The second bridge portions 22 may be spaced apart from each other by the second opening CS2 between the second bridge portions 22.

The second opening CS2 may have substantially the same shape as that of the first opening CS1. In an embodiment, the approximately H-shaped second opening CS2 and the approximately I-shaped second opening CS2 may be alternately and repeatedly disposed in the non-display area, e.g., the first non-display area NDA1. Both end portions of each of the second bridge portions 22 may be connected to the adjacent second island portions 21, and one side of each of the second bridge portions 22 may be spaced apart from one side of the adjacent second island portion 21 and/or one side of another second bridge portion 22 by the second opening CS2, for example.

Each of the second island portions 21 may be connected to four second bridge portions 22. The second island portions 21 may include drivers of the gate driving circuit (refer to GDC of FIG. 3A) described with reference to FIG. 3A.

One row of the second island portions 21 disposed in the first non-display area NDA1 may correspond to one row of the first island portions 11 disposed in the display area DA1. In an embodiment, the second island portions 21 disposed in the i^{th} row in the first direction (e.g., the +x direction or the −x direction) in the first non-display area NDA1 may correspond to the first island portions 11 disposed in the same row, e.g., the i^{th} row, in the display area DA (where i is a positive number greater than 0), for example.

The display device 1 may include third bridge portions 23 disposed in the second sub-non-display area SNDA2 so as to connect the display area DA to the first sub-non-display area SNDA1. The non-display area, e.g., the first non-display area NDA1 may include a first sub-non-display area SNDA1 in which the second island portions 21 and the second bridge portions 22 are arranged, and a second sub-non-display area SNDA2 between the first sub-non-display area SNDA1 and the display area DA and including the third bridge portions 23. The third bridge portion 23 may be substantially the same as the first bridge portion 12 and the second bridge portion 22. In an embodiment, the width of the third bridge portion 23 may be the same as the width of the first bridge portion 12 and the width of the second bridge portion 22, for example.

FIG. 4C is an enlarged plan view of an embodiment of region IV of FIG. 3A as a portion of the display device 1.

Referring to FIG. 4C, the display device 1 may include first island portions 11 spaced apart from each other in the first direction (e.g., the +x direction or the −x direction) and the second direction (e.g., the +y direction or the −y direction) in a display area DA, and first bridge portions 12 extended to the first island portions 11 adjacent to each other.

The first bridge portions 12 may be spaced apart from each other by a first opening CS1 between the first bridge portions 12. The first bridge portion 12 may have a serpentine shape. In an embodiment, as illustrated in FIG. 4C, the first bridge portion 12 may have an approximately S shape, for example.

Each of the first island portions 11 may be extended to a plurality of first bridge portions 12. In an embodiment, each of the first island portions 11 may be extended to four first bridge portions 12, for example. The two first bridge portions 12 may be respectively disposed on opposite sides of the first island portion 11 in the first direction (e.g., the +x direction or the −x direction), and the remaining two first bridge portions 12 may be respectively disposed on opposite sides of the first island portion 11 in the second direction (e.g., the +y direction or the −y direction). The four first bridge portions 12 may be respectively extended to four sides of the first island portion 11. The four first bridge portions 12 may be respectively adjacent to corners of the first island portion 11.

The display device 1 may include second island portions 21 spaced apart from each other in the first direction (e.g., the +x direction or the −x direction) and the second direction (e.g., the +y direction or the −y direction) in the non-display area, e.g., the first non-display area NDA1 illustrated in FIG. 4C, and second bridge portions 22 extended to the second island portions 21 adjacent to each other.

The second bridge portions 22 may be spaced apart from each other by a second opening CS2 between the second bridge portions 22. The second bridge portion 22 may have a serpentine shape. In an embodiment, as illustrated in FIG. 4C, the second bridge portion 22 may have an approximately S shape, for example. The size and/or width of the second bridge portion 22 may be different from the size and/or width of the first bridge portion 12. In an embodiment, the size and/or width of the second bridge portion 22 may be greater than the size and/or width of the first bridge portion 12, for example. The radius of curvature of the round portion of the second bridge portion 22 may be different from the radius of curvature of the round portion of the first bridge portion 12. In an embodiment, the radius of curvature of the round portion of the second bridge portion 22 may be greater than the radius of curvature of the round portion of the first bridge portion 12, for example.

Each of the second island portions 21 may be extended to a plurality of second bridge portions 22. Each of the second island portions 21 may be extended to four second bridge portions 22. The two second bridge portions 22 may be respectively disposed on opposite sides of the second island portion 21 in the first direction (e.g., the +x direction or the −x direction), and the remaining two second bridge portions 22 may be respectively disposed on opposite sides of the second island portion 21 in the second direction (e.g., the +y direction or the −y direction). In an embodiment, the four second bridge portions 22 may be respectively extended to four sides of the second island portion 21. The four second bridge portions 22 may be respectively extended to the central portion of each side of the second island portion 21.

One row of the second island portions 21 disposed in the first non-display area NDA1 may correspond to a plurality of rows of the first island portions 11 disposed in the display area DA1. In an embodiment, one row of the second island portions 21 disposed in the first non-display area NDA1 may correspond to first island portions 11 disposed in an i^{th} row and first island portions 11 disposed in an (i+1)^{th} row in the display area DA (where i is a positive number greater than 0). In another embodiment, one row of the second island portions 21 may correspond to n rows of the first island portions 11 (where n is a positive number greater than or equal to 3), for example.

The non-display area, e.g., the first non-display area NDA1, may include a first sub-non-display area SNDA1 in which the second island portions 21 and the second bridge portions 22 are arranged, and a second sub-non-display area SNDA2 between the first sub-non-display area SNDA1 and the display area DA. Third bridge portions 23 may be disposed in the second sub-non-display area SNDA2 and extend to the display area DA and the first sub-non-display area SNDA1. One end portion of the third bridge portion 23 may be extended to the second island portion 21, and an opposite end portion of the third bridge portion 23 may be extended to the first island portion 11. In an embodiment, one end portion of the third bridge portion 23 may be extended to the central portion of one side of the second island portion 21, and an opposite end portion of the third bridge portion 23 may be extended to the central portion of one side of the first island portion 11, for example.

The third bridge portion 23 may have a serpentine shape. In an embodiment, the shape of the third bridge portion 23 may be different from the shape of the first bridge portion 12 and the shape of the second bridge portion 22. The width of the third bridge portion 23 may be different from the width of the first bridge portion 12 and the width of the second bridge portion 22. The width of the third bridge portion 23 may be greater than the width of the first bridge portion 12 and less than the width of the second bridge portion 22. Third openings CS3 and fourth openings CS4 having different shapes may be alternately between the third bridge portions 23 in the second direction (e.g., the +y direction or the −y direction).

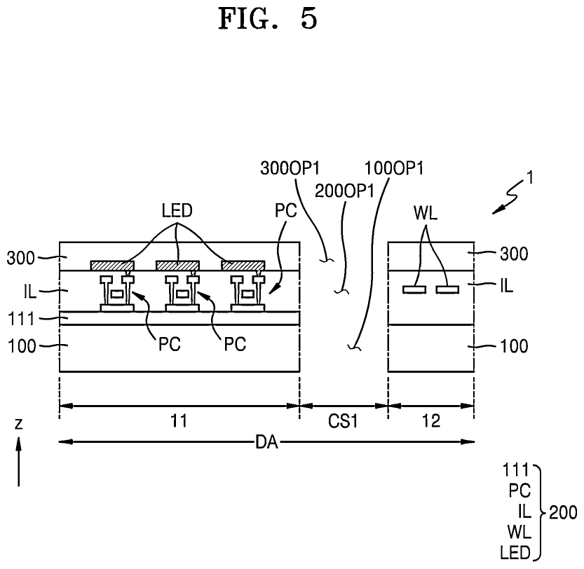

FIG. 5 is a cross-sectional view schematically illustrating an embodiment of the first island portion 11 and the first bridge portion 12, which are arranged in the display area DA of the display device 1.

Referring to FIG. 5, the first island portion 11 and the first bridge portion 12 in the display area DA may be spaced apart from each other with the first opening CS1 therebetween. The first island portion 11 may include light-emitting elements LED and a circuit which drives the light-emitting elements LED electrically connected thereto, such as pixel driving circuits PC. The first bridge portion 12 may include a wiring WL electrically connected to the pixel driving circuits PC respectively disposed in the adjacent first island portions 11.

In the first island portion 11, a buffer layer 111 including an inorganic insulating material may be disposed on a substrate 100, and the pixel driving circuits PC may be disposed on the buffer layer 111. An insulating layer IL including an inorganic insulating material and/or an organic insulating material may be between the pixel driving circuits PC and the light-emitting elements LED. The light-emitting element LED may be disposed on the insulating layer IL and may be electrically connected to the corresponding pixel driving circuit PC. The light-emitting elements LED may emit pieces of light of different colors or the same color. In an embodiment, the light-emitting elements LED may emit red light, green light, and blue light. In some embodiments, the light-emitting elements LED may emit white light. In another embodiment, the light-emitting elements LED may emit red light, green light, blue light, and white light.

The substrate 100 may include polymer resin, such as polyethersulfone, polyarylate, polyether imide, polyethylene naphthalate, polyethylene terephthalate, polyphenylene sulfide, polyimide, polycarbonate, cellulose triacetate, cellulose acetate, or propionate. In an embodiment, the substrate 100 may be a single layer including the polymer resin described above. In another embodiment, the substrate 100 may have a multilayer structure including a base layer including the polymer resin described above and a barrier layer including an inorganic insulating material. The substrate 100 including the polymer resin may be flexible, rollable, and bendable.

In an embodiment, although FIG. 5 illustrates that three pixel driving circuits PC disposed in each of the first island portions 11 and three light-emitting elements LED are respectively connected to the three pixel driving circuits PC, the disclosure is not limited thereto. In another embodiment, the number of pixel driving circuits PC and light-emitting elements LED disposed in the first island portion 11 may be one, two, or four or more.

An encapsulation layer 300 may be disposed on the light-emitting elements LED and may protect the light-emitting elements LED from external force and/or moisture penetration. The encapsulation layer 300 may include an inorganic encapsulation layer and/or an organic encapsulation layer. In some embodiments, the encapsulation layer 300 may include a structure in which an inorganic encapsulation layer including an inorganic insulating material, an organic encapsulating layer including an organic insulating material, and an inorganic encapsulating layer including an inorganic insulating material are stacked in this stated order. In another embodiment, the encapsulation layer 300 may include an organic material such as resin. In some embodiments, the encapsulation layer 300 may include urethane epoxy acrylate. The encapsulation layer 300 may include a photosensitive material such as photoresist.

In the first bridge portion 12, an insulating layer IL including an organic insulating material may be disposed on the substrate 100. When the display device 1 is stretched, the first bridge portion 12, which is relatively deformed, may not have a layer including an inorganic insulating material that is prone to cracks, unlike the first island portion 11.

In an embodiment, the substrate 100 corresponding to the first bridge portion 12 may have the same stack structure as the substrate 100 corresponding to the first island portion 11. In an embodiment, the substrate 100 corresponding to the first bridge portion 12 and the substrate 100 corresponding to the first island portion 11 may be polymer resin layers formed together in the same process. In another embodiment, the substrate 100 corresponding to the first bridge portion 12 may have a different stack structure from the substrate 100 corresponding to the first island portion 11. In some embodiments, the substrate 100 corresponding to the first bridge portion 12 may have a multilayer structure including a base layer including polymer resin and a barrier layer including an inorganic insulating material, and the substrate 100 corresponding to the first bridge portion 12 may have a structure of a polymer resin layer without a layer including an inorganic insulating material.

The wiring WL of the first bridge portion 12 may be a signal line (e.g., a gate line, a data line, etc.) which provides an electrical signal to the transistor included in the pixel driving circuit PC of the first island portion 11, or may be a voltage line (e.g., a driving voltage line, an initialization voltage line, etc.) which provides a voltage to the transistor included in the pixel driving circuit PC of the first island portion 11. An encapsulation layer 300 may also be disposed on the first bridge portion 12. In another embodiment, the encapsulation layer 300 may not be present in the first bridge portion 12.

Referring to FIGS. 4A to 4C and FIG. 5, the substrate 100 corresponding to the first island portion 11 and the substrate 100 corresponding to the first bridge portion 12 may be extended or connected to each other. In other words, the plan views illustrated in FIGS. 4A to 4C may be substantially the same as the plan view of the substrate 100 in FIG. 5. In other words, the substrate 100 may include an area corresponding to the first island portion 11 and an area corresponding to the first bridge portion 12, and may define an opening 100OP1 having the same shape as that of the first opening CS1.

Similarly, the encapsulation layer 300 corresponding to the first island portion 11 and the encapsulation layer 300 corresponding to the first bridge portion 12 may be extended or connected to each other. In an embodiment, the plan views illustrated in FIGS. 4A to 4C may be substantially the same as the plan view of the encapsulation layer 300, for example. In other words, the encapsulation layer 300 may include an area corresponding to the first island portion 11 and an area corresponding to the first bridge portion 12, and may defined an opening 300OP1 having the same shape as that of the first opening CS1.

A circuit light-emitting element layer 200 between the substrate 100 and the encapsulation layer 300 may include a buffer layer 111, a pixel driving circuit PC, a wiring WL, an insulating layer IL, and a light-emitting element LED. Similar to the substrate 100, the plan views illustrated in FIGS. 4A to 4C may be substantially the same as the plan view of the circuit light-emitting element layer 200. In other words, the circuit light-emitting element layer 200 may define an opening 200OP1 having the same shape as that of the first opening CS1.

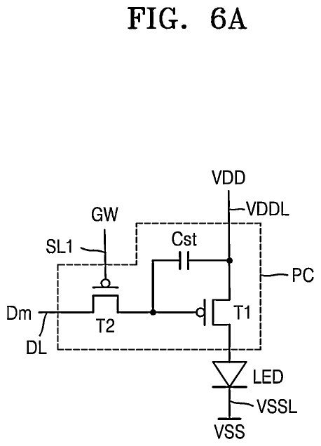

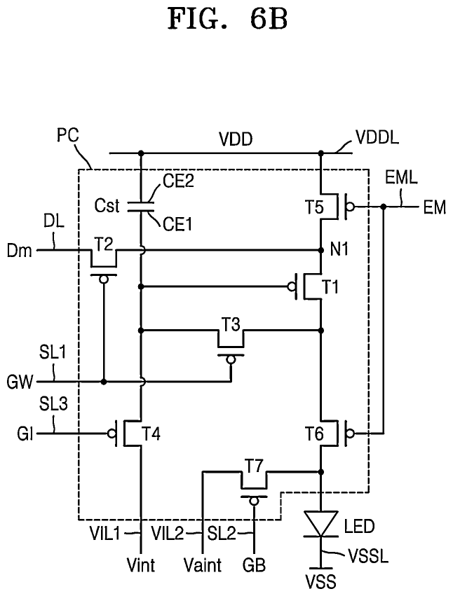

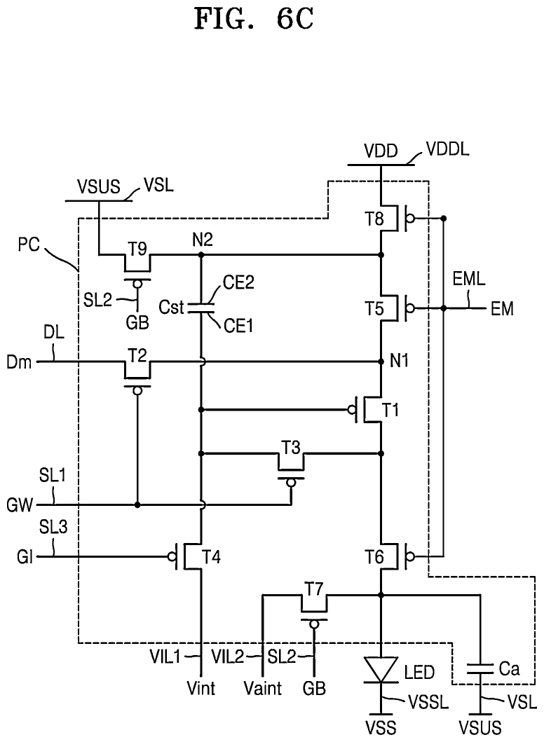

FIGS. 6A to 6C are equivalent circuit diagrams of an embodiment of a sub-pixel of a display device 1.

Referring to FIG. 6A, a light-emitting element LED corresponding to the sub-pixel may be electrically connected to a pixel driving circuit PC, and a pixel driving circuit PC may include a first transistor T1, a second transistor T2, and a storage capacitor Cst. The pixel driving circuit PC may be electrically connected to signal lines and voltage lines. The signal lines may include a gate line, such as a first scan line SL1, and a data line DL, and the voltage lines may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may transmit, to the first transistor T1, a data signal Dm input from the data line DL in response to the first scan signal GW input from the first scan line SL1.

The storage capacitor Cst may be electrically connected to the second transistor T2 and the first voltage line VDDL and may store a voltage corresponding to a difference between a voltage received from the second transistor T2 and a first power supply voltage VDD supplied through the first voltage line VDDL.

The first transistor T1 may act as a driving transistor and may control a driving current flowing through the light-emitting element LED. The first transistor T1 may be connected to the first voltage line VDDL and the storage capacitor Cst. The first transistor T1 may control the driving current flowing from the first voltage line VDDL to the light-emitting element LED according to a voltage value stored in the storage capacitor Cst. The light-emitting element LED may emit light having a predetermined luminance according to the driving current. A first electrode of the light-emitting element LED may be electrically connected to the first transistor T1, and a second electrode may be electrically connected to a second voltage line VSSL which supplies a second power supply voltage VSS.

FIG. 6A illustrates that the pixel driving circuit PC includes two transistors and one storage capacitor, but in another embodiment, the pixel driving circuit PC may include three or more transistors.

Referring to FIG. 6B, the pixel driving circuit PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit PC may be electrically connected to signal lines and voltage lines. The signal lines may include a data line DL and gate lines, such as a first scan line SL1, a second scan line SL2, a third scan line SL3, and an emission control line EML. The voltage lines may include first and second initialization voltage lines VIL1 and VIL2 and a first voltage line VDDL.

The first voltage line VDDL may transmit a first power supply voltage VDD to the first transistor T1. The first initialization voltage line VIL1 may transmit, to the pixel driving circuit PC, a first initialization voltage Vint for initializing the first transistor T1. The second initialization voltage line VIL2 may transmit, to the pixel driving circuit PC, a second initialization voltage Vaint for initializing a first electrode of a light-emitting element LED.

The first transistor T1 may be electrically connected to the first voltage line VDDL via the fifth transistor T5 and may be electrically connected to the light-emitting element LED via the sixth transistor T6. The first transistor T1 may act as a driving transistor and may receive a data signal Dm according to the switching operation of the second transistor T2 and supply a driving current to the light-emitting element LED.

The second transistor T2 may act as a data write transistor and may be electrically connected to the first scan line SL1 and the data line DL. The second transistor T2 may be electrically connected to the first voltage line VDDL via the fifth transistor T5. The second transistor T2 may be turned on in response to a first scan signal GW received through the first scan line SL1 and perform a switching operation to transmit the data signal Dm received through the data line DL to a first node N1.

The third transistor T3 may be electrically connected to the first scan line SL1 and electrically connected to the light-emitting element LED via the sixth transistor T6. The third transistor T3 may be turned on in response to the first scan signal GW received through the first scan line SL1 and diode-connect the first transistor T1.

The fourth transistor T4 may act as a first initialization transistor and may be electrically connected to the third scan line SL3 and the first initialization voltage line VIL1. The fourth transistor T4 may be turned on in response to a third scan signal GI received through the third scan line SL3 and initialize the voltage of the gate electrode of the first transistor T1 by transmitting the first initialization voltage Vint from the first initialization voltage line VIL1 to the gate electrode of the first transistor T1. The third scan signal GI may correspond to the first scan signal of another pixel driving circuit disposed in the previous row of the corresponding pixel driving circuit PC.

The fifth transistor T5 may act as an operation control transistor, and the sixth transistor T6 may act as an emission control transistor. The fifth transistor T5 and the sixth transistor T6 may be electrically connected to the emission control line EML and may be simultaneously turned on in response to an emission control signal EM received through the emission control line EML and form a current path through which the driving current flows in a direction from the first voltage line VDDL to the light-emitting element LED.

The seventh transistor T7 may act as a second initialization transistor and may be electrically connected to the second scan line SL2, the second initialization voltage line VIL2, and the sixth transistor T6. The seventh transistor T7 may be turned on in response to a second scan signal GB received through the second scan line SL2 and initialize the first electrode of the light-emitting element LED by transmitting the second initialization voltage Vaint from the second initialization voltage line VIL2 to the first electrode of the light-emitting element LED.

The storage capacitor Cst may include a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may store and maintain a voltage corresponding to a voltage difference between the first voltage line VDDL and the gate electrode of the first transistor T1, and thus, the voltage applied to the gate electrode of the first transistor T1 may be maintained.

Referring to FIG. 6C, the pixel driving circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit PC may be electrically connected to signal lines and voltage lines. The signal lines may include a data line DL and gate lines, such as a first scan line SL1, a second scan line SL2, a third scan line SL3, and an emission control line EML. The voltage lines may include first and second initialization voltage lines VIL1 and VIL2, a sustain voltage line VSL, and a first voltage line VDDL.

The first voltage line VDDL may transmit a first power supply voltage VDD to the first transistor T1. The first initialization voltage line VIL1 may transmit, to the pixel driving circuit PC, a first initialization voltage Vint for initializing the first transistor T1. The second initialization voltage line VIL2 may transmit, to the pixel driving circuit PC, a second initialization voltage Vaint for initializing a first electrode of a light-emitting element LED. The sustain voltage line VSL may provide a sustain voltage VSUS to a second node N2, e.g., a second electrode CE2 of the storage capacitor Cst, in an initialization period and a data write period.

The first transistor T1 may be electrically connected to the first voltage line VDDL via the fifth transistor T5 and the eighth transistor T8 and may be electrically connected to the light-emitting element LED via the sixth transistor T6. The first transistor T1 may act as a driving transistor and may receive a data signal Dm according to the switching operation of the second transistor T2 and supply a driving current to the light-emitting element LED.

The second transistor T2 may be electrically connected to the first scan line SL1 and the data line DL and electrically connected to the first voltage line VDDL via the fifth transistor T5 and the eighth transistor T8. The second transistor T2 may be turned on in response to a first scan signal GW received through the first scan line SL1 and perform a switching operation to transmit, to a first node N1, the data signal Dm transmitted through the data line DL.

The third transistor T3 may be electrically connected to the first scan line SL1 and electrically connected to the light-emitting element LED via the sixth transistor T6. The third transistor T3 may be turned on in response to the first scan signal GW received through the first scan line SL1 and compensate for a threshold voltage of the first transistor T1 by diode-connecting the first transistor T1.

The fourth transistor T4 may be electrically connected to the third scan line SL3 and the first initialization voltage line VIL1 and may be turned on in response to a third scan signal GI received through the third scan line SL3 and initialize the voltage of the gate electrode of the first transistor T1 by transmitting the first initialization voltage Vint from the first initialization voltage line VIL1 to the gate electrode of the first transistor T1. The third scan signal GI may correspond to the first scan signal of another pixel driving circuit disposed in the previous row of the corresponding pixel driving circuit PC.

The fifth transistor T5, the sixth transistor T6, and the eighth transistor T8 may be electrically connected to the emission control line EML and may be simultaneously turned on in response to an emission control signal EM received through the emission control line EML and form a current path through which the driving current flows in a direction from the first voltage line VDDL to the light-emitting element LED.

The seventh transistor T7 may act as a second initialization transistor and may be electrically connected to the second scan line SL2, the second initialization voltage line VIL2, and the sixth transistor T6. The seventh transistor T7 may be turned on in response to a second scan signal GB received through the second scan line SL2 and initialize the first electrode of the light-emitting element LED by transmitting the second initialization voltage Vaint from the second initialization voltage line VIL2 to the first electrode of the light-emitting element LED.

The ninth transistor T9 may be electrically connected to the second scan line SL2, the second electrode CE2 of the storage capacitor Cst, and the sustain voltage line VSL. The ninth transistor T9 may be turned on in response to the second scan signal GB received through the second scan line SL2 and transmit the sustain voltage VSUS to the second node N2, e.g., the second electrode CE2 of the storage capacitor Cst, in the initialization period and the data write period.

The eighth transistor T8 and the ninth transistor T9 may be electrically connected to the second scan line N2, e.g., the second electrode CE2 of the storage capacitor Cst. In some embodiments, in the initialization period and the data write period, the eighth transistor T8 may be turned off and the ninth transistor T9 may be turned on, and in the emission period, the eighth transistor T8 may be turned on and the ninth transistor T9 may be turned off. Because the sustain voltage VSUS is transmitted to the second node N2 in the initialization period and the data write period, the luminance uniformity (e.g., long range uniformity (“LRU”)) of the display device according to the voltage drop of the first voltage line VDDL may be improved.

The storage capacitor Cst may include a first electrode CE1 and a second electrode CE2. The first electrode CE1 of the storage capacitor Cst may be electrically connected to the gate electrode of the first transistor T1, and the second electrode CE2 of the storage capacitor Cst may be electrically connected to the eighth transistor line T8 and the ninth transistor T9.

The auxiliary capacitor Ca may be electrically connected to the sixth transistor T6, the sustain voltage line VSL, and the first electrode of the light-emitting element LED. The auxiliary capacitor Ca may store and maintain a voltage corresponding to a voltage difference between the first electrode of the light-emitting element LED and the sustain voltage line VSL while the seventh transistor T7 and the ninth transistor T9 are turned on, and thus, the problem that increases black luminance when the sixth transistor T6 is turned off may be prevented.

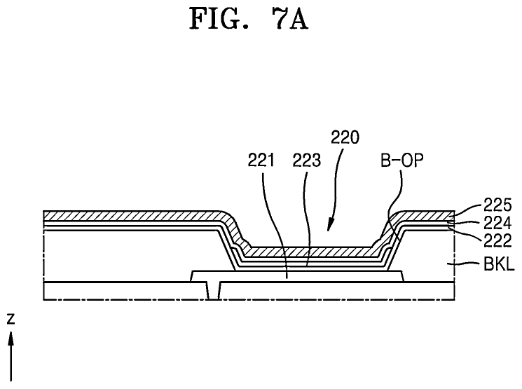

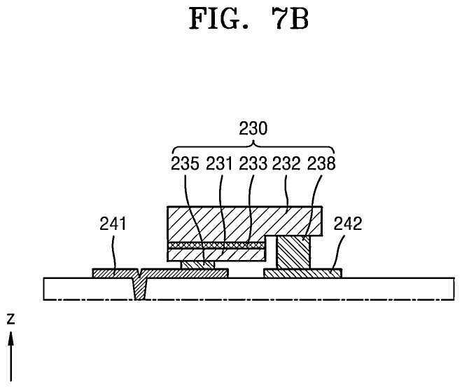

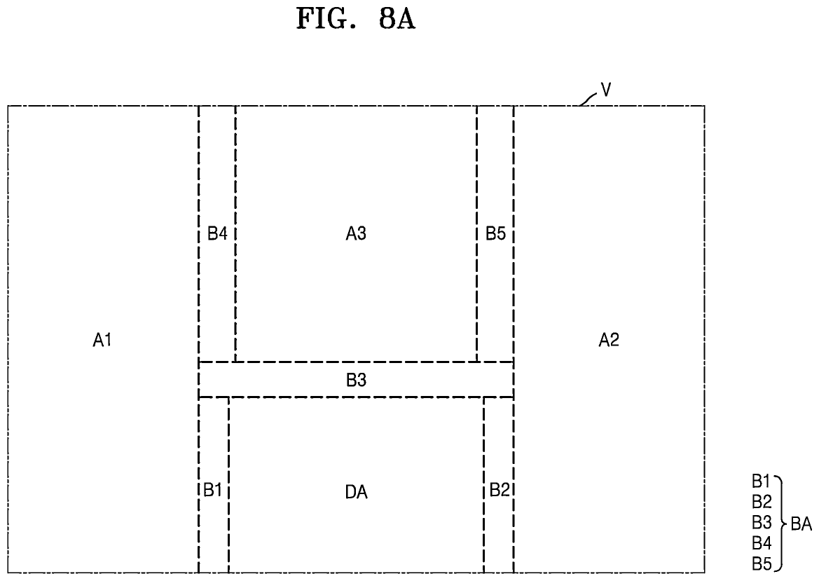

FIG. 7A is a cross-sectional view schematically illustrating an embodiment of a light-emitting element of a display device.

Referring to FIG. 7A, the light-emitting element in an embodiment may include an organic light-emitting diode 220 including an organic material. The organic light-emitting diode 220 may include a first electrode 221 disposed on an insulating layer, a second electrode 225 facing the first electrode 221, and an emission layer 223 between the first electrode 221 and the second electrode 225. A first functional layer 222 may be between the first electrode 221 and the emission layer 223, and a second functional layer 224 may be between the emission layer 223 and the second electrode 225.

The edge of the first electrode 221 may be covered with a bank layer BKL including an insulating material. The bank layer BKL may define an opening B-OP overlapping the central portion of the first electrode 221.

The first electrode 221 may include a conductive oxide, such as indium tin oxide (“ITO”), indium zinc oxide IZO, zinc oxide (ZnO), indium oxide (In₂O₃), indium gallium oxide (“IGO”), or aluminum zinc oxide (“AZO”). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any combination thereof. In another embodiment, the first electrode 221 may further include a layer including ITO, IZO, ZnO, AZO, or In₂O₃ above and/or below the reflective layer.

The emission layer 223 may include a relatively high molecular weight organic material or a relatively low molecular weight organic material that emits light of a predetermined color. The first functional layer 222 may include a hole transport layer (“HTL”) and/or a hole injection layer (“HIL”). The second functional layer 224 may include an electron transport layer (“ETL”) and/or an electron injection layer (“EIL”).

The second electrode 225 may include a conductive material having a relatively low work function. In an embodiment, the second electrode 225 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof, for example. In an alternative embodiment, the second electrode 225 may further include a layer including ITO, IZO, ZnO, AZO, or In₂O₃ on the (semi) transparent layer including the material described above.

FIG. 7B is a cross-sectional view schematically illustrating an embodiment of a light-emitting element of a display device.

Referring to FIG. 7B, the light-emitting element in an embodiment may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be respectively electrically connected to a first electrode pad 241 and a second electrode pad 242, which are arranged in the same layer.

In some embodiments, the first semiconductor layer 231 may include a p-type semiconductor layer. The p-type semiconductor layer may be selected from semiconductor materials having a composition formula of InₓAl_{y}Ga_{1-x-y}N (0≤x≤1, 0≤y≤1, 0≤x+y≤1), e.g., GaN, AlN, AlGaN, InGaN, InN, InAlGaN, or AlInN, and may be doped with a p-type dopant, such as Mg, Zn, Ca, Sr, or Ba.

The second semiconductor layer 232 may include, e.g., an n-type semiconductor layer. The n-type semiconductor layer may be selected from semiconductor materials having a composition formula of InₓAl_{y}Ga_{1-x-y}N (0≤x≤1, 0≤y≤1, 0≤x+y≤1), e.g., GaN, AlN, AlGaN, InGaN, InN, InAlGaN, or AlInN, and may be doped with an n-type dopant, such as Si, Ge, or Sn.

The intermediate layer 233 is an area in which electrons and holes recombine. As the electrons and the holes recombine, the intermediate layer 233 may transition to a relatively low energy level to generate light having a wavelength corresponding thereto. In an embodiment, the intermediate layer 233 may include a semiconductor material having a composition formula of InₓAl_{y}Ga_{1-x-y}N (0≤x≤1, 0≤y≤1, 0≤x+y≤1), and may have a single quantum well structure or a multi quantum well (“MQW”) structure, for example. In addition, the intermediate layer 233 may have a quantum wire structure or a quantum dot structure.

Although FIG. 7B illustrates that the first semiconductor layer 231 includes a p-type semiconductor layer and the second semiconductor layer 232 includes an n-type semiconductor layer, the disclosure is not limited thereto. In another embodiment, the first semiconductor layer 231 may include an n-type semiconductor layer and the second semiconductor layer 232 may include a p-type semiconductor layer.

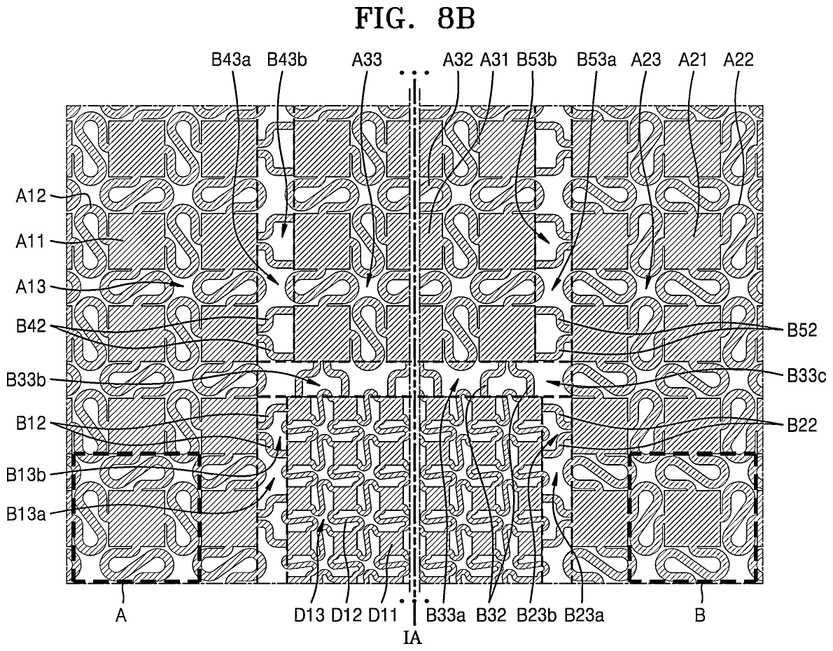

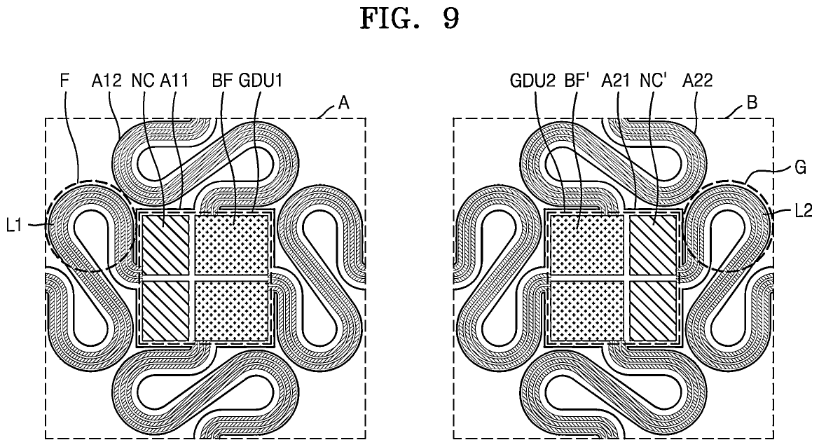

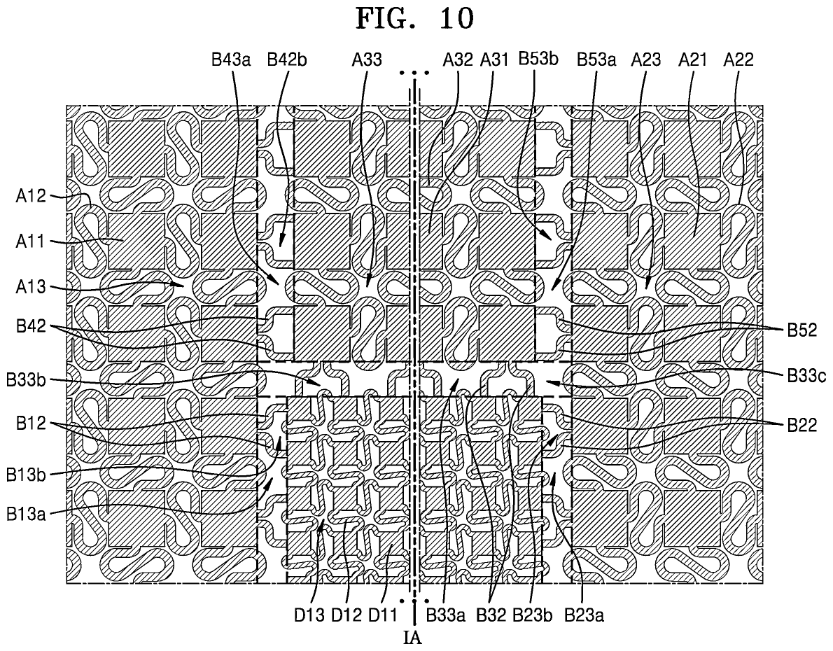

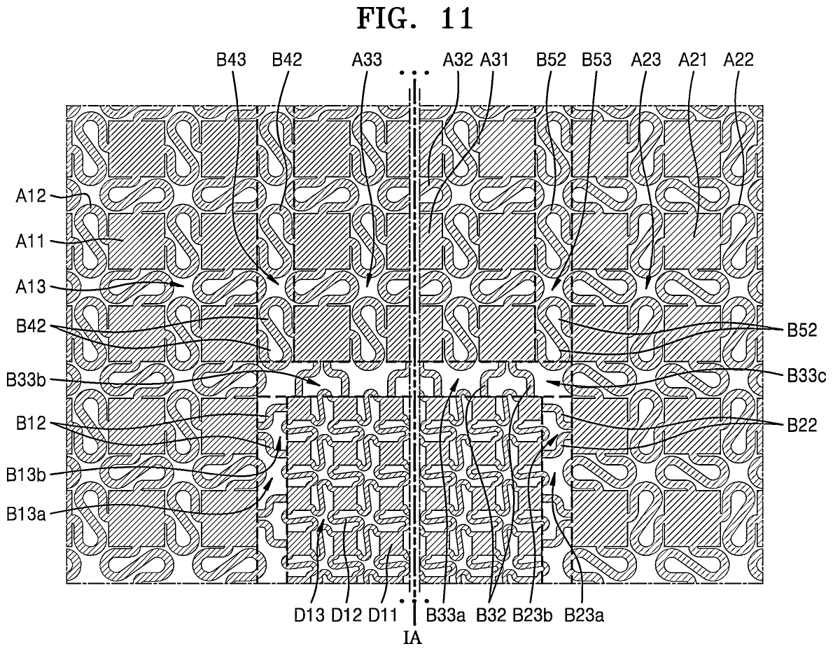

FIG. 8A is a diagram schematically illustrating an embodiment of a partial area included in the display device 1, and FIG. 8B is an enlarged plan view illustrating an embodiment of a portion of the display device 1. FIGS. 8A and 8B are enlarged views of region V of FIG. 3B. FIG. 9 is an enlarged plan view of an embodiment of regions A and B of FIG. 8B as a portion of the display device 1. FIGS. 10 and 11 are enlarged plan views illustrating another embodiment of a portion of the display device 1 and illustrate a modification of FIG. 8B.

Referring to FIG. 8A, a first peripheral area A1, a second peripheral area A2, and a third peripheral area A3 may be disposed around a display area DA. An intermediate area BA may be between the first peripheral area A1, the second peripheral area A2, and the third peripheral area A3. The intermediate area BA may be included in the non-display area NDA. The intermediate area BA may include a first intermediate area B1, a second intermediate area B2, a third intermediate area B3, a fourth intermediate area B4, and a fifth intermediate area B5. The first intermediate area B1 may be between the display area DA and the first peripheral area A1. The second intermediate area B2 may be between the display area DA and the second peripheral area A2. The third intermediate area B3 may be disposed between the display area DA and the third peripheral area A3. The fourth intermediate area B4 may be between the first peripheral area A1 and the third peripheral area A3. The fifth intermediate area B5 may be between the third peripheral area A3 and the second peripheral area A2. A bridge portion and/or an opening, which are to be described below, may be disposed in the intermediate area BA.

Referring to FIGS. 8A and 8B, the display device 1 may include main island portions D11 spaced apart from each other and disposed in a matrix form in the first direction (e.g., the +x direction or the −x direction) and the second direction (e.g., the +y direction or the −y direction) in the display area DA, and main bridge portions D12 connecting the adjacent main island portions D11 to each other. The main bridge portions D12 may be spaced apart from each other by main openings D13 between the main bridge portions D12.

In an embodiment, the structure of the display area DA in FIG. 8B may be the same as the structure of the display area DA described with reference to FIG. 4C. In an embodiment, the main island portion D11, the main bridge portion D12, and the main opening D13 in the display area DA may correspond to the first island portion 11, the first bridge portion 12, and the first opening CS1 in the display area DA described with reference to FIG. 4C, for example.

The main bridge portion D12 may have a serpentine shape. In an embodiment, the main bridge portion D12 may have an approximate S shape, for example. The main island portions D11 may be respectively extended to the main bridge portions D12. In an embodiment, the main island portions D11 may each be extended to two main bridge portions D12 disposed on opposite sides of the main island portion D11 in the first direction (e.g., the +x direction or the −x direction) and two main bridge portions D12 disposed on opposite sides of the main island portion D11 in the second direction (e.g., the +y direction or the −y direction), for example. The four main bridge portions D12 may be adjacent to corners of the main island portion D11.

The display device 1 may include first peripheral island portions A11 spaced apart from each other and disposed in a matrix form in the first direction (e.g., the +x direction or the −x direction) and the second direction (e.g., the +y direction or the −y direction in the peripheral area A1, and first peripheral bridge portions A12 connecting the adjacent first adjacent island portions A11 to each other. The first peripheral bridge portions A12 may be spaced apart from each other by first peripheral openings A13 disposed between the first peripheral island portions A11.

In an embodiment, the structure of the first peripheral area A1 in FIG. 8B may be the same as the structure of the first non-display area NDA1 described with reference to FIG. 4C. In an embodiment, the first peripheral island portion A11, the first peripheral bridge portion A12, and the first peripheral opening A13 in the first peripheral area A1 may correspond to the second island portion 21, the second bridge portion 22, and the second opening CS2 in the first non-display area NDA1 (e.g., the first sub-non-display area SNDA1) described with reference to FIG. 4C, for example.

The first peripheral bridge portion A12 may have a serpentine shape. In an embodiment, the first peripheral bridge portion A12 may have an approximate S shape, for example. The first peripheral bridge portions A12 may be respectively extended to the first peripheral island portions A11. In an embodiment, the first peripheral island portions A11 may each be extended to two first peripheral bridge portions A12 disposed on opposite sides of the first peripheral island portion A11 in the first direction (e.g., the +x direction or the −x direction) and two first peripheral bridge portions A12 disposed on opposite sides of the first peripheral island portion A11 in the second direction (e.g., the +y direction or the −y direction), for example. The four first peripheral bridge portions A12 may each be extended to the central portion of each side of the first peripheral island portion A11.

The display device 1 may include second peripheral island portions A21 spaced apart from each other and second peripheral bridge portions A22 connecting the adjacent second peripheral island portions A21 to each other in the second peripheral area A2. The second peripheral bridge portions A22 may be spaced apart from each other by second peripheral openings A23 disposed between the second peripheral island portions A21.

The second peripheral bridge portion A22 may have a serpentine shape. In an embodiment, the second peripheral bridge portion A22 may have a shape in which an approximately S shape is left and right reversed, for example. The second peripheral bridge portions A22 may be respectively extended to the second peripheral island portions A21. In an embodiment, the second peripheral island portions A21 may each be extended to two second peripheral bridge portions A22 disposed on opposite sides of the second peripheral island portion A21 in the first direction (e.g., the +x direction or the −x direction) and two second peripheral bridge portions A22 disposed on opposite sides of the second peripheral island portion A21 in the second direction (e.g., the +y direction or the −y direction), for example. The four second peripheral bridge portions A22 may each be extended to the central portion of each side of the second peripheral island portion A21.

The first peripheral area A1 and the second peripheral area A2 may have a symmetrical structure with respect to a center line IA. The center line IA may be disposed between the first peripheral area A1 and the second peripheral area A2 and may be disposed at the same distance from the first peripheral area A1 and the second peripheral area A2. The center line IA may pass through the center of the display area DA and may extend in the second direction (e.g., the +y direction or the −y direction). Specifically, the first peripheral island portions A11 of the first peripheral area A1 and the second peripheral island portions A21 of the second peripheral area A2 may be disposed symmetrically with respect to the center line IA. The first peripheral bridge portions A12 of the first peripheral area A1 and the second peripheral bridge portions A22 of the second peripheral area A2 may be disposed symmetrically with respect to the center line IA.

The second peripheral island portions A21 and the first peripheral island portions A11 may have a symmetrical shape with respect to the center line IA. The second peripheral bridge portions A22 and the first peripheral bridge portions A12 may have a symmetrical shape with respect to the center line IA. In an embodiment, the first peripheral bridge portions A12 may have an approximately S shape, and the second peripheral bridge portions A22 may have a shape in which an approximately S shape is left and right reversed, for example.

In some embodiments, as described with reference to FIG. 3A, gate driving circuits may be disposed in the first peripheral area A1 and the second peripheral area A2. At least some first peripheral island portions A11 in the first peripheral area A1 may include driver units of the gate driving circuit disposed on the left side. The first peripheral bridge portions A12 may include wirings electrically connected to driver units of the first peripheral island portions A11 adjacent to each other. In addition, at least some second peripheral island portions A21 in the second peripheral area A2 may include driver units of the gate driving circuit disposed on the right side. The second peripheral bridge portions A22 may include wirings electrically connected to driver units of the second peripheral island portions A21 adjacent to each other.

The gate driving circuit may include a plurality of stages each of which outputs a gate signal. The stages may sequentially output gate signals based on a control signal. The driver units may each include at least one stage. The driver unit may include a node controller and a buffer transistor. The node controller may include a plurality of transistors and a plurality of capacitors and may control the voltage of the node by a start signal or the like provided through an input terminal. The buffer transistor may be disposed to isolate a signal source from a circuit driven by the signal source. In addition, the wirings connected to the gate driving circuit may be signal lines which provide electrical signals to the gate driving circuit and/or voltage lines which provide voltages to the gate driving circuit. The wirings may correspond to a clock wiring which provides a clock signal to the gate driving circuit, a gate high-voltage wiring which applies a driving voltage, and a gate low-voltage wiring, for example.

The driver units included in the first peripheral island portions A11 and the driver units included in the second peripheral island portions A21 may be disposed symmetrically with respect to the center line IA. The wirings included in the first peripheral bridge portions A12 and the wirings included in the second peripheral bridge portions A22 may be disposed symmetrically with respect to the center line IA.

Referring to FIG. 9, for example, the first peripheral island portion A11 in region A may include a first driver unit GDU1, and the first driver unit GDU1 may include a node controller NC and a buffer transistor BF. The second peripheral island portion A21 in region B may include a second driver unit GDU2, and the second driver unit GDU2 may include a node controller NC′ and a buffer transistor BF′. The first driver unit GDU1 and the second driver unit GDU2 may be disposed symmetrically with respect to the center line IA. In an embodiment, in the first driver unit GDU1, the node controller NC may be disposed on the left side and the buffer transistor BF may be disposed on the right side, for example. In the second driver unit GDU2, the node controller NC′ may be disposed on the right side and the buffer transistor BF′ may be disposed on the left side.

In addition, the first peripheral bridge portion A12 extended to the left side of the first peripheral island portion A11 in region A may include a first wiring L1 electrically connected to the first driver unit GDU1. The second peripheral bridge portion A22 extended to the right side of the second peripheral island portion A21 in region B may include a second wiring L2 electrically connected to the second driver unit GDU2. The first wiring L1 of the first peripheral bridge portion A12 and the second wiring L2 of the second peripheral bridge portion A22 may be disposed symmetrically with respect to the center line IA.

Referring to FIG. 9, the first peripheral bridge portion A12 and the second peripheral bridge portion A22 may each have a serpentine shape. Because pressure (strain) may be applied inside the bent portion, a region (refer to F and G) where the formation of wirings is impossible may be present. That is, the first peripheral bridge portion A12 and the second peripheral bridge portion A22 may have an area (e.g., F and G) in which wiring design is possible. As illustrated in FIG. 9, the area where wiring design is possible may vary depending on the bending direction in the shape of the bridge portion.

In a comparative example, when the first island portions of the first peripheral area and the second island portions of the second peripheral area are not disposed symmetrically with respect to the center line, or when the first peripheral bridge portions of the first peripheral area and the second peripheral bridge portions of the second peripheral area are not disposed symmetrically with respect to the center line, the driver units and wirings in the first peripheral area and the driver units and wirings in the second peripheral area may be differently designed, and a deviation may occur between the output of the gate driving circuit in the first peripheral area and the output of the gate driving circuit in the second peripheral area.

In an embodiment, when the driver units included in the first peripheral island portions and the driver units included in the second peripheral island portions are arranged symmetrically and the first peripheral bridge portions and the second peripheral bridge portions are formed to have the same shape while performing an inversion design to symmetrically arrange the wirings included in the first peripheral bridge portion and the wirings included in the second peripheral bridge portion, the wirings of the first peripheral bridge portion and the wirings of the second peripheral bridge portion may be differently designed depending on restrictions on the area in which wiring design is possible according to the shape of the bridge portion, for example. Accordingly, the driver units of the first peripheral island portions and the driver units of the second peripheral island portions may also be differently designed. In this case, due to the different design between the driver units and wirings in the first peripheral area and the driver units and wirings in the second peripheral area, a deviation may occur between the output of the gate driving circuit in the first peripheral area and the output of the gate driving circuit in the second peripheral area.

However, in an embodiment, the first peripheral island portions A11 of the first peripheral area A1 and the second peripheral island portions A21 of the second peripheral area A2 may be disposed symmetrically with respect to the center line IA, and the first peripheral bridge portions A12 of the first peripheral area A1 and the second peripheral bridge portions A22 of the second peripheral area A2 may be disposed symmetrically with respect to the center line IA. Specifically, the driver units included in the first peripheral island portions A11 and the driver units included in the second peripheral island portions A21 may be disposed symmetrically with respect to the center line IA, and the second peripheral island portions A21 and the first peripheral island portions A11 may have symmetrical shape with respect the center line IA. The wirings included in the first peripheral bridge portions A12 and the wirings included in the second peripheral bridge portions A22 may be disposed symmetrically with respect to the center line IA. The second peripheral island portions A21 and the first peripheral island portions A11 may have a symmetrical shape. In this case, the driver units and wirings in the first peripheral area A1 and the driver units and wirings in the second peripheral area A2 may be designed to be equal to each other. Accordingly, a deviation between the output of the gate driving circuit in the first peripheral area A1 and the output of the gate driving circuit in the second peripheral area A2 may be removed.

Referring back to FIGS. 8A and 8B, the display device 1 may include third peripheral island portions A31 spaced apart from each other and third peripheral bridge portions A32 connecting the adjacent third peripheral island portions A31 to each other in the third peripheral area A3. The third peripheral bridge portions A32 may be spaced apart from each other by third peripheral openings A33 disposed between the third peripheral island portions A31.

In an embodiment, as illustrated in FIG. 8B, the structure of the third peripheral area A3 may be the same as the structure of the first peripheral area A1. The arrangement structure of the third peripheral island portions A31, the third peripheral bridge portions A32, and the third peripheral openings A33 in the third peripheral area A3 may be substantially the same as the arrangement structure of the first peripheral island portions A11, the first peripheral bridge portions A12, and the first peripheral openings A13 in the first peripheral area A1. In addition, the third peripheral island portions A31, the third peripheral bridge portions A32, and the third peripheral openings A33 in the third peripheral area A3 may respectively have substantially the same shapes as the first peripheral island portions A11, the first peripheral bridge portions A12, and the first peripheral openings A13 in the first peripheral area A1. In an embodiment, the third peripheral bridge portion A32 may have the same shape as that of the first peripheral bridge portion A12, for example. The third peripheral bridge portion A32 may have a serpentine shape. In an embodiment, the third peripheral bridge portion A32 may have an approximate S shape, for example.

However, the disclosure is not limited thereto. In another embodiment, as illustrated in FIG. 10, the structure of the third peripheral area A3 may be the same as the structure of the second peripheral area A2. The arrangement structure of the third peripheral island portions A31, the third peripheral bridge portions A32, and the third peripheral openings A33 in the third peripheral area A3 may be substantially the same as the arrangement structure of the second peripheral island portions A21, the second peripheral bridge portions A22, and the second peripheral openings A23 in the second peripheral area A2. In addition, the third peripheral island portions A31, the third peripheral bridge portions A32, and the third peripheral openings A33 in the third peripheral area A3 may respectively have substantially the same shapes as the second peripheral island portions A21, the second peripheral bridge portions A22, and the second peripheral openings A23 in the second peripheral area A2. In an embodiment, the third peripheral bridge portion A32 may have the same shape as that of the second peripheral bridge portion A22, for example. The third peripheral bridge portion A32 may have a serpentine shape. In an embodiment, the third peripheral bridge portion A32 may have a shape in which an approximately S shape is left and right reversed, for example.

At least some of the third peripheral island portions A31 and the third peripheral bridge portions A32 in the third peripheral area A3 may be dummy island portions or dummy bridge portions, which do not include driving circuits or wirings. Some of the third peripheral island portions A31 and the third peripheral bridge portions A32 may include wirings. In an embodiment, some of the third peripheral island portions A31 and the third peripheral bridge portions A32 may include wirings connected to the gate driving circuit disposed in the first peripheral area A1 or the second peripheral area A2, for example.

Bridge portions may be disposed in the intermediate area BA. First intermediate bridge portions B12 may be disposed in the first intermediate area B1 and extend to the display area DA and the first peripheral area A1. One end portion of the first intermediate bridge portion B12 may be extended to the first peripheral island portion A11 and/or the first peripheral bridge portion A12, and an opposite end portion of the first intermediate bridge portion B12 may be extended to the main island portion D11 and/or the main bridge portion D12.

In an embodiment, the structure of the first intermediate area B1 in FIG. 8B may be the same as the structure of the second sub-non-display area SNDA2 described with reference to FIG. 4C. In an embodiment, the first intermediate bridge portion B12 of the first intermediate area B1 may correspond to the third bridge portion 23 of the second sub-non-display area SNDA2 described with reference to FIG. 4C, for example.

The first intermediate bridge portion B12 may have a serpentine shape. In an embodiment, the shape of the first intermediate bridge portion B12 may be different from the shape of the main bridge portion D12 and the shape of the first peripheral bridge portion A12. The width of the first intermediate bridge portion B12 may be different from the width of the main bridge portion D12 and/or the width of the first peripheral bridge portion A12. In an embodiment, the width of the first intermediate bridge portion B12 may be greater than the width of the main bridge portion D12 and less than the width of the first peripheral bridge portion A12, for example. 1^{st}−1 intermediate openings B13a and 1^{st}−2 intermediate openings B13b having different shapes may be alternately between the first intermediate bridge portions B12 in the second direction (e.g., the +y direction or the −y direction).

Second intermediate bridge portions B22 may be disposed in the second intermediate area B2 and extend to the display area DA and the second peripheral area A2. One end portion of the second intermediate bridge portion B22 may be extended to the second peripheral island portion A21 and/or the second peripheral bridge portion A22, and an opposite end portion of the second intermediate bridge portion B22 may be extended to the main island portion D11 and/or the main bridge portion D12.

The second intermediate bridge portion B22 may have a serpentine shape. In an embodiment, the shape of the second intermediate bridge portion B22 may be different from the shape of the main bridge portion D12 and the shape of the second peripheral bridge portion A22. The width of the second intermediate bridge portion B22 may be different from the width of the main bridge portion D12 and/or the width of the first peripheral bridge portion A12. In an embodiment, the width of the second intermediate bridge portion B22 may be greater than the width of the main bridge portion D12 and less than the width of the first peripheral bridge portion A12. 2^{nd}−1 intermediate openings B23a and 2^{nd}−2 intermediate openings B23b having different shapes may be alternately between the second intermediate bridge portions B22 in the second direction (e.g., the +y direction or the −y direction), for example.

Third intermediate bridge portions B32 may be disposed in the third intermediate area B3 and extend to the display area DA and the third peripheral area A3. One end portion of the third intermediate bridge portion B32 may be extended to the third peripheral island portion A31 and/or the third peripheral bridge portion A32, and an opposite end portion of the third intermediate bridge portion B32 may be extended to the main island portion D11 and/or the main bridge portion D12.

The third intermediate bridge portion B32 may have a serpentine shape. In an embodiment, the shape of the third intermediate bridge portion B32 may be different from the shape of the main bridge portion D12 and the shape of the third peripheral bridge portion A32. The width of the third intermediate bridge portion B32 may be different from the width of the main bridge portion D12 and/or the width of the third peripheral bridge portion A32. In an embodiment, the width of the third intermediate bridge portion B32 may be greater than the width of the main bridge portion D12 and equal to the width of the third peripheral bridge portion A32, for example. 3^{rd}−1 intermediate openings B33a and 3^{rd}−2 intermediate openings B33b having different shapes may be alternately between the third intermediate bridge portions B32 in the first direction (e.g., the +x direction or the −x direction). 3^{rd}−3 intermediate openings B33c having a different shape from the 3^{rd}−1 intermediate openings B33a and the 3^{rd}−2 intermediate openings B33b may be disposed at both end portions of the third intermediate area B3 in the first direction (e.g., the +x direction or the −x direction).

Fourth intermediate bridge portions B42 may be disposed in the fourth intermediate area B4 and extend to the first peripheral area A1 and the third peripheral area A3. One end portion of the fourth intermediate bridge portion B42 may be extended to the first peripheral island portion A11 and/or the first peripheral bridge portion A12, and an opposite end portion of the fourth intermediate bridge portion B42 may be extended to the third peripheral island portion A31 and/or the third peripheral bridge portion A32.

The fourth intermediate bridge portion B42 may have a serpentine shape. In an embodiment, as illustrated in FIG. 8B, the shape of the fourth intermediate bridge portion B42 may be different from the shape of the first peripheral bridge portion A12 and the shape of the third peripheral bridge portion A32. However, the disclosure is not limited thereto. In an another, as illustrated in FIG. 11, the shape of the fourth intermediate bridge portion B42 may be substantially the same as the shape of the first peripheral bridge portion A12 and/or the shape of the third peripheral bridge portion A32. In an embodiment, the fourth intermediate bridge portion B42 may have an approximate S shape, for example.

In an embodiment, the width of the fourth intermediate bridge portion B42 may be substantially the same as the width of the first peripheral bridge portion A12 and the width of the third peripheral bridge portion A32. However, the disclosure is not limited thereto. In another embodiment, the width of the fourth intermediate bridge portion B42 may be different from the width of the first peripheral bridge portion A12 and/or the width of the third peripheral bridge portion A32. 4^{th}−1 intermediate openings B43a and 4^{th}−2 intermediate openings B43b having different shapes may be alternately between the fourth intermediate bridge portions B42 in the second direction (e.g., the +y direction or the −y direction).

Fifth intermediate bridge portions B52 may be disposed in the fifth intermediate area B5 and extend to the second peripheral area A2 and the third peripheral area A3. One end portion of the fifth intermediate bridge portion B52 may be extended to the second peripheral island portion A21 and/or the second peripheral bridge portion A22, and an opposite end portion of the fifth intermediate bridge portion B52 may be extended to the third peripheral island portion A31 and/or the third peripheral bridge portion A32.

The fifth intermediate bridge portion B52 may have a serpentine shape. In an embodiment, the shape of the fifth intermediate bridge portion B52 may be different from the shape of the second peripheral bridge portion A22 and the shape of the third peripheral bridge portion A32. However, the disclosure is not limited thereto. In another embodiment, as illustrated in FIG. 11, the shape of the fifth intermediate bridge portion B52 may be substantially the same as the shape of the second peripheral bridge portion A22 and/or the shape of the third peripheral bridge portion A32. In an embodiment, the fourth intermediate bridge portion B42 may have an approximate S shape, which is the same shape as that of the third peripheral bridge portion A32, for example. In an embodiment, the width of the fifth intermediate bridge portion B52 may be substantially the same as the width of the second peripheral bridge portion A22 and the width of the third peripheral bridge portion A32. However, the disclosure is not limited thereto. In another embodiment, the width of the fifth intermediate bridge portion B52 may be different from the width of the second peripheral bridge portion A22 and/or the width of the third peripheral bridge portion A32. 5^{th}−1 intermediate openings B53a and 5^{th}−2 intermediate openings B53b having different shapes may be alternately between the fifth intermediate bridge portions B52 in the second direction (e.g., the +y direction or the −y direction).

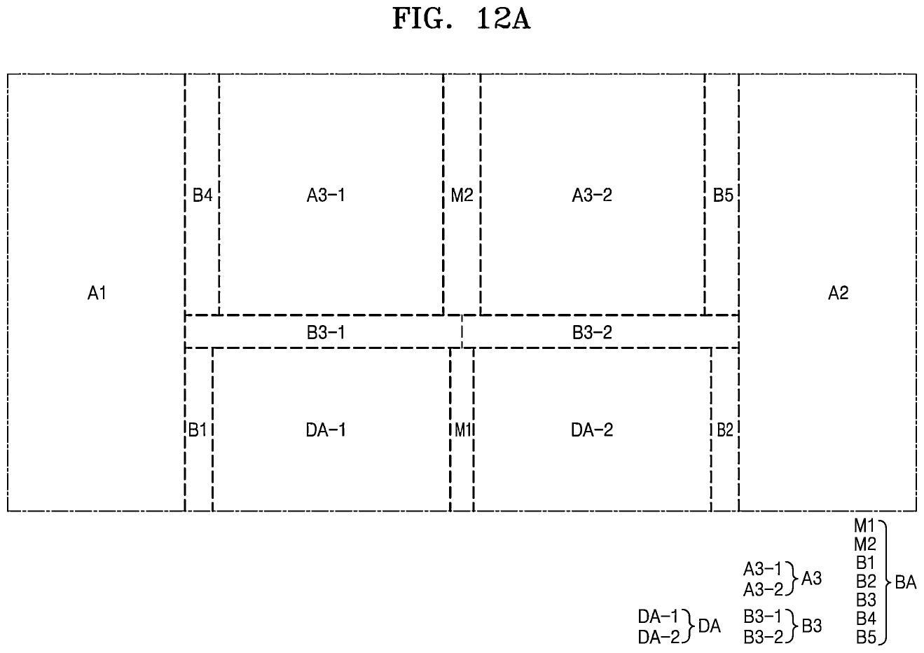

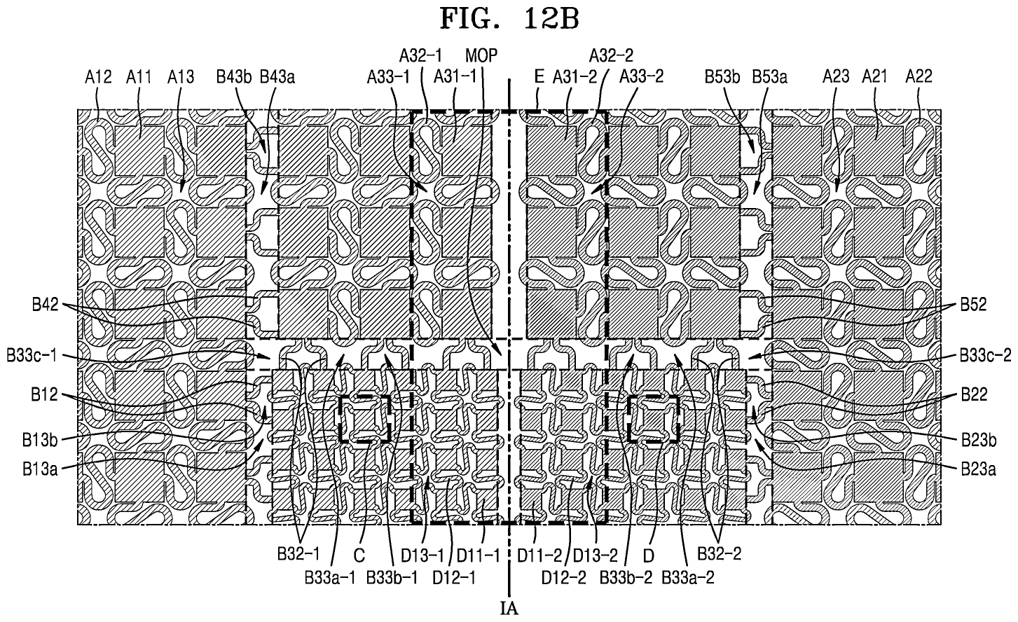

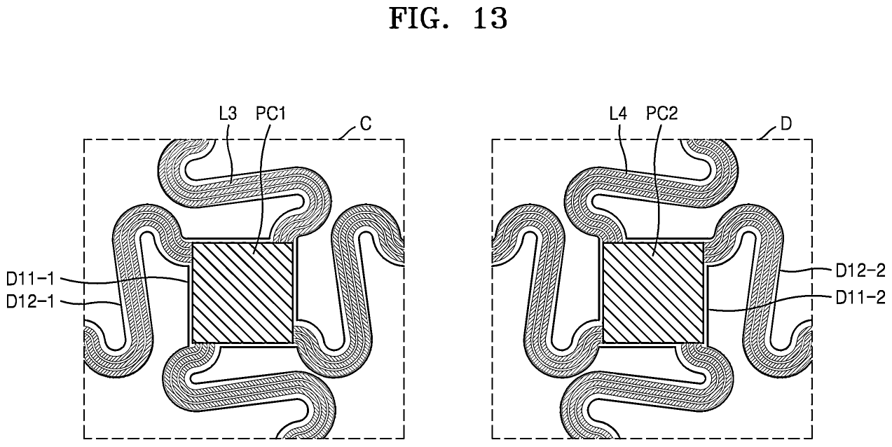

FIG. 12A is a diagram schematically illustrating an embodiment of a partial area included in the display device, and FIG. 12B is an enlarged plan view illustrating an embodiment of a portion of the display device 1. FIGS. 12A and 12B are modifications of FIGS. 8A and 8B, and the modifications differ from the above-described embodiments in the structure of the display area DA, the third peripheral area A3, and the intermediate area BA. The differences are mainly described below and overlapping descriptions are omitted. FIG. 13 is an enlarged plan view of an embodiment of regions C and D of FIG. 12B as a portion of the display device 1.

Referring to FIG. 12A, a first peripheral area A1, a second peripheral area A2, and a third peripheral area A3 may be disposed around a display area DA. The display area DA may include a first display area DA-1 and a second display area DA-2 with a center line IA therebetween. The third peripheral area A3 may include a first sub-area A3-1 and a second sub-area A3-2 with the center line IA therebetween.

An intermediate area BA may be between the first peripheral area A1, the second peripheral area A2, and the third peripheral area A3. The intermediate area BA may include a first intermediate area B1, a second intermediate area B2, a third intermediate area B3, a fourth intermediate area B4, a fifth intermediate area B5, a first central area M1, and a second central area M2. The first central area M1 may be between the first display area DA-1 and the second display area DA-2. The second central area M2 may be between the first sub-area A3-1 and the second sub-area A3-2 of the third peripheral area A3. The third intermediate area B3 may include a first sub-area B3-1 and a second sub-area B3-2 respectively on opposite sides of the center line IA. A bridge portion and/or an opening may be disposed in the intermediate area BA.

Referring to FIGS. 12A and 12B, main island portions (refer to D11 of FIG. 8B), main bridge portions (refer to D12 of FIG. 8B), and main openings (refer to D13 of FIG. 8B) may be disposed in the display area DA of the display device 1. Although FIG. 12B illustrates 12 rows of main island portions D11 disposed in the display area DA, the disclosure is not limited thereto. In an embodiment, 13 or more rows of main island portions D11 may be disposed in the display area DA, for example.

The main island portions D11 disposed in the first display area DA-1 may be first main island portions D11-1, and the main island portions D11 disposed in the second display area DA-2 may be second main island portions D11-2. The main bridge portions D12 disposed in the first display area DA-1 may be first main bridge portions D12-1, and the main bridge portions D12 disposed in the second display area DA-2 may be second main bridge portions D12-2. The main openings D13 disposed in the first display area DA-1 may be first main openings D13-1, and the main openings D13 disposed in the second display area DA-2 may be second main openings D13-2.

The first main island portions D11-1 and the second main island portions D11-2 may be disposed symmetrically with respect to the center line IA. The first main bridge portions D12-1 and the second main bridge portions D12-2 may be disposed symmetrically with respect to the center line IA.

The first main island portions D11-1 and the second main island portions D11-2 may have a symmetrical shape with respect to the center line IA. The first main bridge portions D12-1 and the second main bridge portions D12-2 may have a symmetrical shape with respect to the center line IA. In an embodiment, the first main bridge portions D12-1 may have an approximately S shape, and the second main bridge portions D12-2 may have a shape in which an approximately S shape is left and right reversed.

As described above with reference to FIG. 5, the main island portions D11 may each include a light-emitting element constituting a pixel and a circuit (e.g., a pixel driving circuit) which is electrically connected to the light-emitting element and drives the light-emitting element. The pixel driving circuit may include transistors and at least one capacitor. The main bridge portions D12 may include wirings electrically connected to pixel driving circuits arranged in the adjacent main island portions D11. The wirings electrically connected to the pixel driving circuits may be a signal line (e.g., a gate line, a data line, etc.) which provides an electrical signal to the transistor included in the pixel driving circuit, or a voltage line (e.g., a driving voltage line, an initialization voltage line, etc.) which provides a voltage to the transistor included in the pixel driving circuit.

The pixel driving circuits included in the first main island portions D11-1 and the pixel driving circuits included in the second main island portions D11-2 may be disposed symmetrically with respect to the center line IA. The wirings included in the first main bridge portions D12-1 and the wirings included in the second main bridge portions D12-2 may be disposed symmetrically with respect to the center line IA.

Referring to FIG. 13, for example, the first main island portion D11-1 of region C may include a first pixel driving circuit PC1 and the second main island portion D11-2 of region D may include a second pixel driving circuit PC2. The first pixel driving circuit PC1 and the second pixel driving circuit PC2 may be disposed symmetrically with respect to the center line IA. In addition, the first main bridge portion D12-1 extended to the upper side of the first main island portion D11-1 of region C may include a third wiring L3 electrically connected to the first pixel driving circuit PC1. The second main bridge portion D12-2 extended to the upper side of the second main island portion D11-2 of region D may include a fourth wiring L4 electrically connected to the second pixel driving circuit PC2. The third wiring L3 and the fourth wiring L4 may be disposed symmetrically with respect to the center line IA.

Referring back to FIGS. 12A and 12B, third peripheral island portions (refer to A31 of FIG. 8B), third peripheral bridge portions (refer to A32 of FIG. 8B), and third peripheral openings (refer to A33 of FIG. 8B) may be disposed in the third peripheral area A3 of the display device 1. Although FIG. 12B illustrates six rows of third peripheral island portions A31 disposed in the third peripheral area A3, the disclosure is not limited thereto. In an embodiment, seven or more rows of third peripheral island portions A31 may be disposed in the third peripheral area A3, for example.

The third peripheral island portions A31 disposed in a first sub-area A3-1 may be 3^{rd}−1 peripheral island portions A31-1, and the third peripheral island portions A31 disposed in a second sub-area A3-2 may be 3^{rd}−2 peripheral island portions A31-2. The third peripheral bridge portions A32 disposed in the first sub-area A3-1 may be 3^{rd}−1 peripheral bridge portions A32-1, and the third peripheral bridge portions A32 disposed in the second sub-area A3-2 may be 3^{rd}−2 peripheral bridge portions A32-2. The third peripheral openings A33 disposed in the first sub-area A3-1 may be 3^{rd}−1 peripheral openings A33-1, and the third peripheral openings A33 disposed in the second sub-area A3-2 may be 3^{rd}−2 peripheral openings A33-2.

The 3^{rd}−1 peripheral island portions A31-1 and the 3^{rd}−2 peripheral island portions A31-2 may be disposed symmetrically with respect to the center line IA. The 3^{rd}−1 peripheral bridge portions A32-1 and the 3^{rd}−2 peripheral bridge portions A32-2 may be disposed symmetrically with respect to the center line IA.

The 3^{rd}−1 peripheral island portions A31-1 and the 3^{rd}−2 peripheral island portions A31-2 may have a symmetrical shape with respect to the center line IA. The 3^{rd}−1 peripheral bridge portions A32-1 and the 3^{rd}−2 peripheral bridge portions A32-2 may have a symmetrical shape with respect to the center line IA. In an embodiment, the 3^{rd}−1 peripheral bridge portions A32-1 may have an approximately S shape, and the 3^{rd}−2 peripheral bridge portions A32-2 may have a shape in which an approximately S shape is left and right reversed, for example.

Third intermediate bridge portions (refer to B32 of FIG. 8B), 3^{rd}−1 intermediate openings (refer to B33a of FIG. 8B) having different shapes, 3^{rd}−2 intermediate openings B33b, and 3^{rd}−3 intermediate openings (refer to B33c of FIG. 8B) may be disposed in the third intermediate area B3 of the display device 1.

The third intermediate bridge portions B32 disposed in the first sub-area B3-1 may be 3^{rd}−1 intermediate bridge portions B32-1, and the third intermediate bridge portions B32 disposed in the second sub-area B3-2 may be 3^{rd}−2 intermediate bridge portions B32-2. The 3^{rd}−1 intermediate openings B33a disposed in the first sub-area B3-1 may be 3^{rd}−1-1 intermediate openings B33a-1, and the 3^{rd}−1 intermediate openings B33a disposed in the second sub-area B3-2 may be 3^{rd}−1-2 intermediate openings B33a-2. The 3^{rd}−2 intermediate openings B33b disposed in the first sub-area B3-1 may be 3^{rd}−2−1 intermediate openings B33b-1, and the 3^{rd}−2 intermediate openings B33b disposed in the second sub-area B3-2 may be 3^{rd}−2−2 intermediate openings B33b-2. The 3^{rd}−3 intermediate openings B33c disposed in the first sub-area B3-1 may be 3^{rd}−3−1 intermediate openings B33c-1, and the 3^{rd}−3 intermediate openings B33c disposed in the second sub-area B3-2 may be 3^{rd}−3−2 intermediate openings B33c-2.

In an embodiment, the 3^{rd}−1 intermediate bridge portions B32-1 and the 3^{rd}−2 intermediate bridge portions B32-2 may be disposed symmetrically with respect to the center line IA. The 3^{rd}−1 intermediate bridge portions B32-1 and the 3^{rd}−2 intermediate bridge portions B32-2 may have a symmetrical shape with respect to the center line IA.

In an embodiment, an opening through which the center line IA passes may be between the 3^{rd}−1 intermediate bridge portions B32-1 and the 3^{rd}−2 intermediate bridge portion B32-2, which are adjacent to each other.

The display device 1 may include a first central area M1 and a second central area M2, through which the center line IA passes. The first central area M1 may be between the first display area DA-1 and the second display area DA-2. The second central area M2 may be between the first sub-area B3-1 and the second sub-area B3-2.

In an embodiment, openings MOP corresponding to the first central area M1 and the second central area M2 may be respectively disposed in the first central area M1 and the second central area M2. In an embodiment, the openings MOP may correspond to the first central area M1, an area between the 3^{rd}−1 intermediate bridge portion B32-1 and the 3^{rd}−2 intermediate bridge portion B32-2 adjacent to each other in the third intermediate area B3, and the second central area M2, for example. In other words, bridge portions may not be disposed in the first central area M1 and the second central area M2.

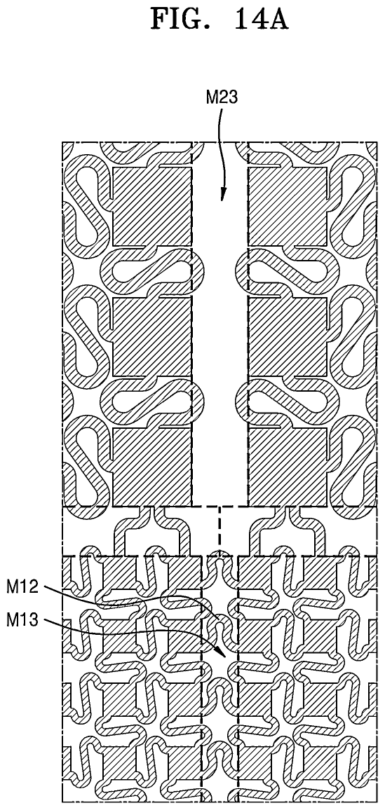

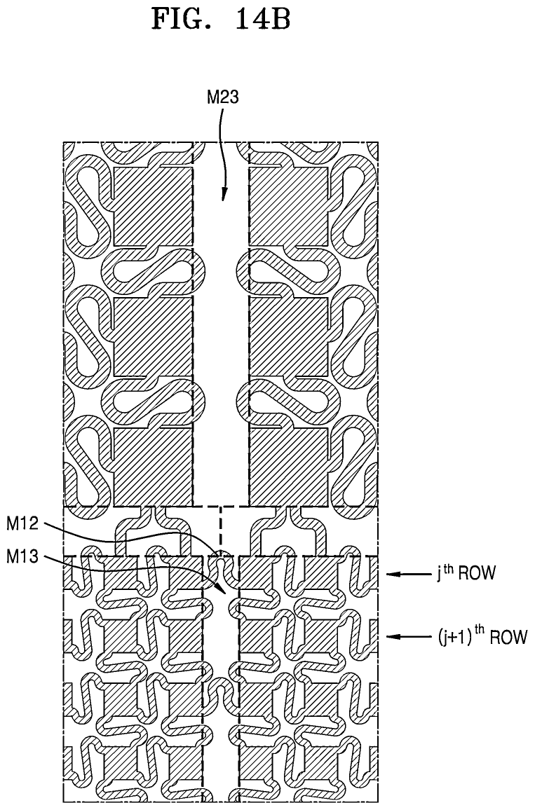

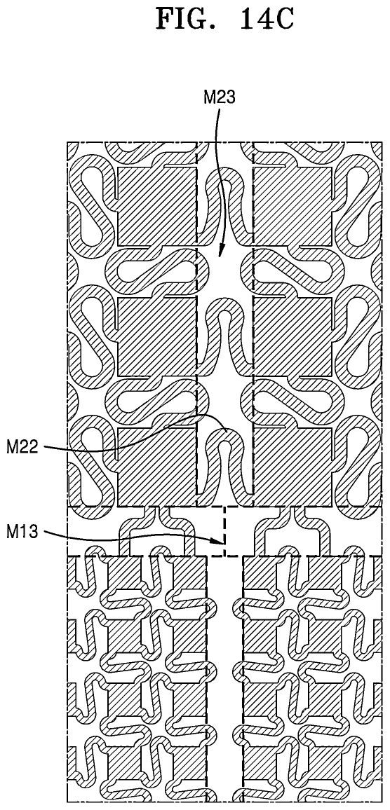

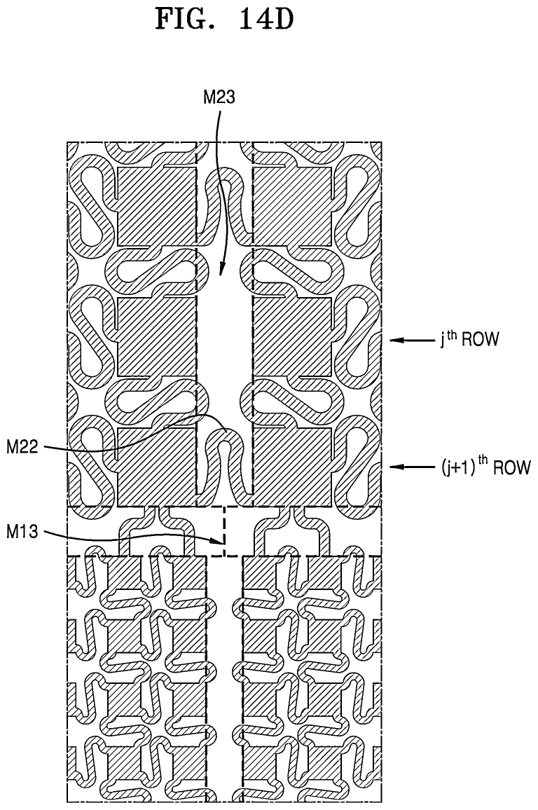

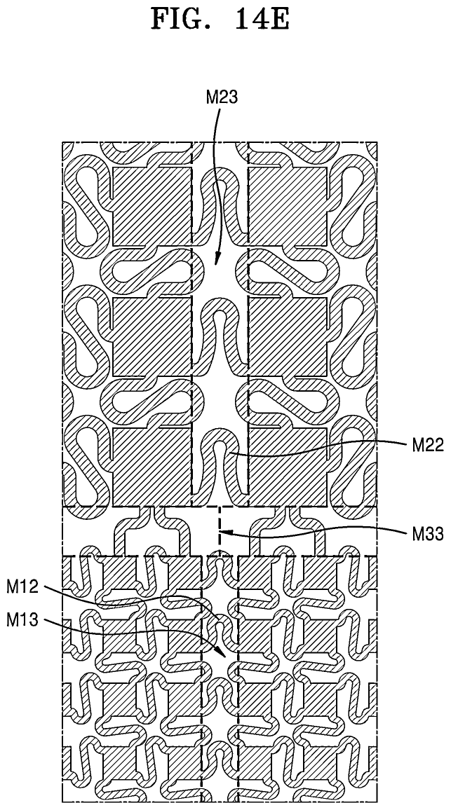

FIGS. 14A and 14B are enlarged plan views of another embodiment of region E of FIG. 12B as a portion of a display device. FIGS. 14A and 14B are modifications of FIG. 12B, and the modifications differ from the above-described embodiments in the structure of the first central area M1 and the second central area M2. The differences are mainly described below and overlapping descriptions are omitted.

Referring to FIGS. 12B and 14A, in an embodiment, first central bridge portions M12 may be disposed in the first central area M1 and extend to a first display area DA-1 and a second display area DA-2 of a display area DA. One end portion of the first central bridge portion M12 may be extended to a first main island portion D11-1 and/or a first main bridge portion D12-1, and an opposite end portion of the first central bridge portion M12 may be extended to a second main island portion D11-2 and/or a second main bridge portion D12-2.

The first central bridge portion M12 may have a serpentine shape. In an embodiment, the shape of the first central bridge portion M12 may be different from the shape of the first main bridge portion D12-1 and the shape of the second main bridge portion D12-2. In an embodiment, as illustrated in FIG. 14A, the first central bridge portion M12 may have an approximately omega (Ω) shape that is convex in the second direction (e.g., the +y direction). In an embodiment, one end portion of the first central bridge portion M12 may be extended to a portion adjacent to a corner of one side of the first main bridge portion D12-1, and an opposite end portion of the first central bridge portion M12 may be extended to a portion adjacent to a corner of one side of the second main bridge portion D12-2, for example. The adjacent first central bridge portions M12 may be spaced apart from each other by first central openings M13.

In an embodiment, openings M23 corresponding to the second central area M2 may be disposed in the second central area M2. In an embodiment, the openings M23 may correspond to the second central area M2 and an area between the 3^{rd}−1 intermediate bridge portion B32-1 and the 3^{rd}−2 intermediate bridge portion B32-2 adjacent to each other in the third intermediate area B3, for example. In other words, bridge portions may not be disposed in the second central area M2.

FIG. 14B is a modification of FIG. 14A. Referring to FIG. 14B, in an embodiment, the first central bridge portions M12 may be disposed in the first central area M1 in accordance with a predetermined rule. In an embodiment, the first central bridge portions M12 may be only between the first main island portion D11-1 and the second main island portion D11-2 in some rows. In an embodiment, the first central bridge portions M12 may be between the first main island portion D11-1 and the second main island portion D11-2 disposed in a j^{th} row, and may not be between the first main island portion D11-1 and the second main island portion D11-2 disposed in a (j+1)^{th} row (where j is an odd number), for example. However, the disclosure is not limited thereto, and the first central bridge portions M12 may be disposed in accordance with various rules.

FIGS. 14C and 14D are enlarged plan views of another embodiment of region E of FIG. 12B as a portion of a display device. FIGS. 14C and 14D are modifications of FIG. 12B, and the modifications differ from the above-described embodiments in the structure of the first central area M1 and the second central area M2. The differences are mainly described below and overlapping descriptions are omitted.

Referring to FIGS. 12B and 14C, in an embodiment, openings M13 corresponding to the first central area M1 may be disposed in the first central area M1. In an embodiment, the openings M13 may correspond to the first central area M1 and an area between the 3^{rd}−1 intermediate bridge portion B32-1 and the 3^{rd}−2 intermediate bridge portion B32-2 adjacent to each other in the third intermediate area B3, for example. In other words, bridge portions may not be disposed in the first central area M1.

Second central bridge portions M22 may be disposed in the second central area M2 and extend to the first sub-area A3-1 and the second sub-area A3-2 of the third peripheral area A3. One end portion of the second central bridge portion M22 may be extended to the 3^{rd}−1 peripheral island portion A31-1 and/or the 3^{rd}−1 peripheral bridge portion A32-1, and an opposite end portion of the second central bridge portion M22 may be extended to the 3^{rd}−2 peripheral island portion A31-2 and/or the 3^{rd}−2 peripheral bridge portion A32-2.

The second central bridge portion M22 may have a serpentine shape. In an embodiment, the shape of the second central bridge portion M22 may be different from the shape of the 3^{rd}−1 peripheral bridge portion A32-1 and the shape of the 3^{rd}−2 peripheral bridge portion A32-2. In an embodiment, as illustrated in FIG. 14C, the second central bridge portion M22 may have an approximately omega (Ω) shape that is convex in the second direction (e.g., the +y direction). In this case, one end portion of the second central bridge portion M22 may be extended to a portion adjacent to a corner of one side of the 3^{rd}−1 peripheral island portion A31-1, and an opposite end portion of the second central bridge portion M22 may be extended to a portion adjacent to a corner of one side of the 3^{rd}−2 peripheral island portion A31-2. The adjacent second central bridge portions M22 may be spaced apart from each other by second central openings M23.

FIG. 14D is a modification of FIG. 14C. Referring to FIG. 14D, in an embodiment, the second central bridge portions M22 may be disposed in the second central area M2 in accordance with a predetermined rule. In an embodiment, the second central bridge portions M22 may be only between the 3^{rd}−1 peripheral island portion A31-1 and the 3^{rd}−2 peripheral island portion A31-2 in some rows. In an embodiment, the second central bridge portions M22 may not be between the 3^{rd}−1 peripheral island portion A31-1 and the 3^{rd}−2 peripheral island portion A31-2 disposed in a j^{th} row, and may be between the 3^{rd}−1 peripheral island portion A31-1 and the 3^{rd}−2 peripheral island portion A31-2 disposed in a (j+1)^{th} row (where j is an odd number), for example. However, the disclosure is not limited thereto, and the second central bridge portions M22 may be disposed in accordance with various rules.

FIG. 14E is an enlarged plan view of another embodiment of region E of FIG. 12B as a portion of a display device. FIG. 14E is a modification of FIG. 12A, and the modification differs from the above-described embodiments in the structure of the first central area M1 and the second central area M2. The differences are mainly described below and overlapping descriptions are omitted.

In an embodiment, first central bridge portions M12 may be disposed in the first central area M1 and extend to the first display area DA-1 and the second display area DA-2. One end portion of the first central bridge portion M12 may be extended to a first main island portion D11-1 and/or a first main bridge portion D12-1, and an opposite end portion of the first central bridge portion M12 may be extended to a second main island portion D11-2 and/or a second main bridge portion D12-2.

The first central bridge portion M12 may have a serpentine shape. In an embodiment, the shape of the first central bridge portion M12 may be different from the shape of the first main bridge portion D12-1 and the shape of the second main bridge portion D12-2. In an embodiment, the first central bridge portion M12 may have an approximately omega (Ω) shape that is convex in the second direction (e.g., the +y direction). In this case, one end portion of the first central bridge portion M12 may be extended to a portion adjacent to a corner of one side of the first main bridge portion D12-1, and an opposite end portion of the first central bridge portion M12 may be extended to a portion adjacent to a corner of one side of the second main bridge portion D12-2. The adjacent first central bridge portions M12 may be spaced apart from each other by first central openings M13.

In an embodiment, second central bridge portions M22 may be disposed in the second central area M2 and extend to the first sub-area A3-1 and the second sub-area A3-2 of the third peripheral area A3. One end portion of the second central bridge portion M22 may be extended to the 3^{rd}−1 peripheral island portion A31-1 and/or the 3^{rd}−1 peripheral bridge portion A32-1, and an opposite end portion of the second central bridge portion M22 may be extended to the 3^{rd}−2 peripheral island portion A31-2 and/or the 3^{rd}−2 peripheral bridge portion A32-2.

The second central bridge portion M22 may have a serpentine shape. In an embodiment, the shape of the second central bridge portion M22 may be different from the shape of the 3^{rd}−1 peripheral bridge portion A32-1 and the shape of the 3^{rd}−2 peripheral bridge portion A32-2. In an embodiment, as illustrated in FIG. 14C, the second central bridge portion M22 may have an approximately omega (Ω) shape that is convex in the second direction (e.g., the +y direction). In an embodiment, one end portion of the second central bridge portion M22 may be extended to a portion adjacent to a corner of one side of the 3^{rd}−1 peripheral island portion A31-1, and an opposite end portion of the second central bridge portion M22 may be extended to a portion adjacent to a corner of one side of the 3^{rd}−2 peripheral island portion A31-2, for example. The width of the second central bridge portion M22 may be different from the width of the first central bridge portion M12. The width of the second central bridge portion M22 may be greater than the width of the first central bridge portion M12. The adjacent second central bridge portions M22 may be spaced apart from each other by second central openings M23.

An opening through which the center line IA passes may be between the 3^{rd}−1 intermediate bridge portions B32-1 and the 3^{rd}−2 intermediate bridge portion B32-2, which are adjacent to each other.

Although FIG. 14E illustrates that the first central bridge portions M12 are arranged in all rows in the first central area M1, the disclosure is not limited thereto. In another embodiment, the first central bridge portions M12 may be disposed in the first central area M1 in accordance with a predetermined rule. The first central bridge portions M12 may be only between the first main island portion D11-1 and the second main island portion D11-2 in some rows. In addition, although FIG. 14E illustrates that the second central bridge portions M22 are arranged in all rows in the second central area M2, the disclosure is not limited thereto. In another embodiment, the second central bridge portions M22 may be disposed in the second central area M2 in accordance with a predetermined rule. The second central bridge portions M22 may be only between the 3^{rd}−1 peripheral island portion A31-1 and the 3^{rd}−2 peripheral island portion A31-2 in some rows.

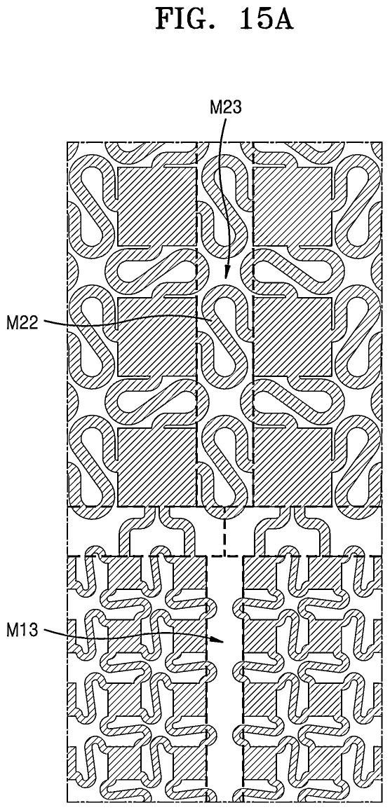

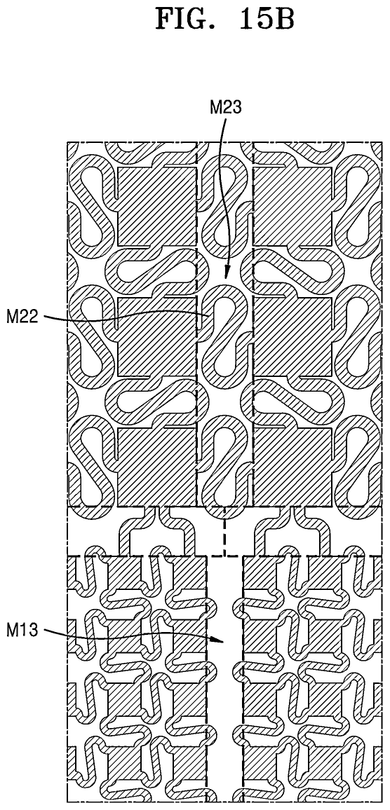

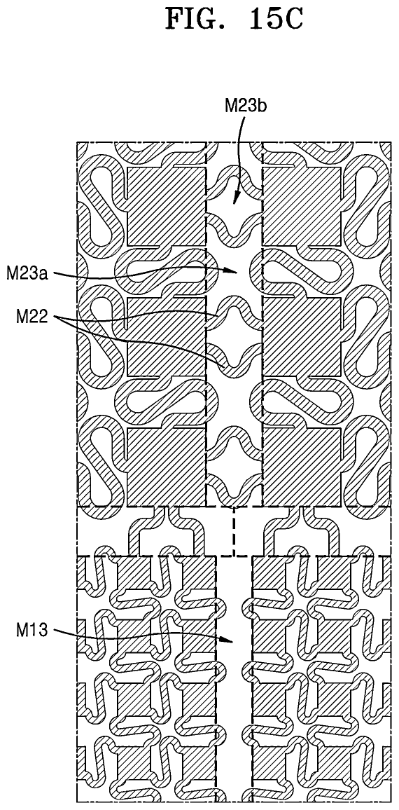

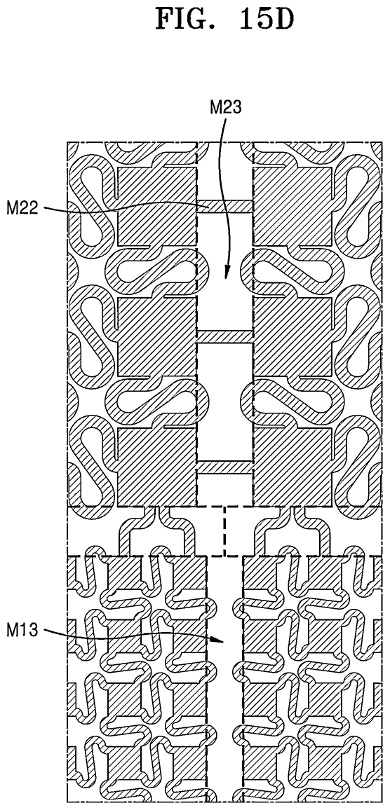

FIGS. 15A to 15D are enlarged plan views of another embodiment of region E of FIG. 12B as a portion of a display device. FIGS. 15A to 15D are modifications of FIG. 14C, and the modifications differ from the above-described embodiments in the shape of the second central bridge portion M22. The differences are mainly described below and overlapping descriptions are omitted.

The shape of the second central bridge portion M22 of FIGS. 15A to 15D may be substantially equally applied to the shape of the first central bridge portion M12. In addition, the description of FIGS. 15A to 15D is based on the structure of FIG. 14C, but may also be applied to the structures of FIGS. 14A, 14B, 14D, and 14E.

Referring to FIGS. 15A and 15B, the second central bridge portion M22 may have a serpentine shape. In an embodiment, the shape of the second central bridge portion M22 may be substantially the same as the shape of the 3^{rd}−1 peripheral bridge portion A32-1 and/or the shape of the 3^{rd}−2 peripheral bridge portion A32-2. In an embodiment, as illustrated in FIG. 15A, the shape of the second central bridge portion M22 may be substantially the same as the shape of the 3^{rd}−1 peripheral bridge portion A32-1. In an embodiment, the second central bridge portion M22 may have an approximate S shape, for example. In addition, in another embodiment, as illustrated in FIG. 15B, the shape of the second central bridge portion M22 may be substantially the same as the shape of the 3^{rd}−2 peripheral bridge portion A32-2. In an embodiment, the second central bridge portion M22 may have a shape in which an approximately S shape is left and right reversed, for example.

Referring to FIG. 15C, the second central bridge portion M22 may have a serpentine shape. In an embodiment, the second central bridge portion M22 may have an approximately omega (Ω) shape that is convex in the second direction (e.g., the +y direction or the −y direction). The second central bridge portions M22 disposed in the second direction (e.g., the +y direction or the −y direction) may have a symmetrical structure in which one thereof is convex in the +y direction and another one thereof is convex in the −y direction. 2^{nd}−1 central openings M23a and 2^{nd}−2 central openings M23b having different shapes may be repeated between the second central bridge portions M22.

Referring to FIG. 15D, in an embodiment, the second central bridge portion M22 may have a straight-line shape. In an embodiment, the second central bridge portion M22 may have a straight-line shape extending in the first direction (e.g., the +x direction or the −x direction), for example.

However, the shape of the second central bridge portion M22 of the second central area M2 and the shape of the first central bridge portion M12 of the first central area M1 are not limited to the shapes illustrated in FIGS. 15A to 15D and may be variously designed.

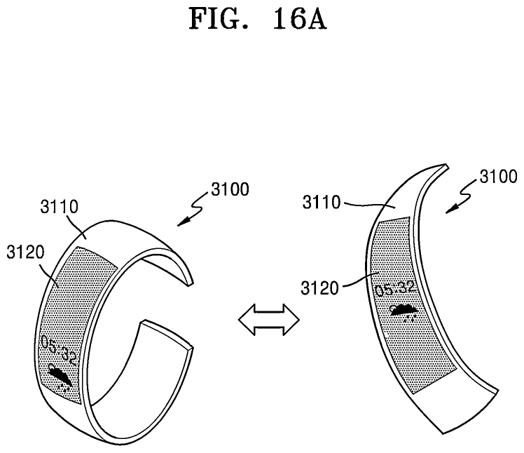

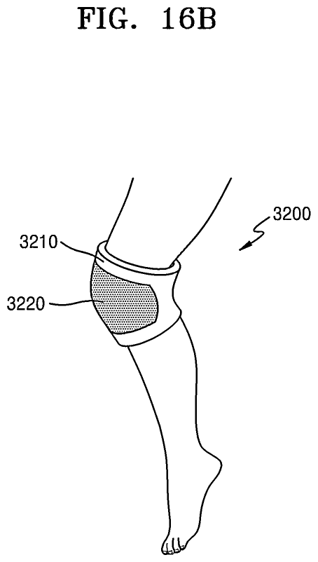

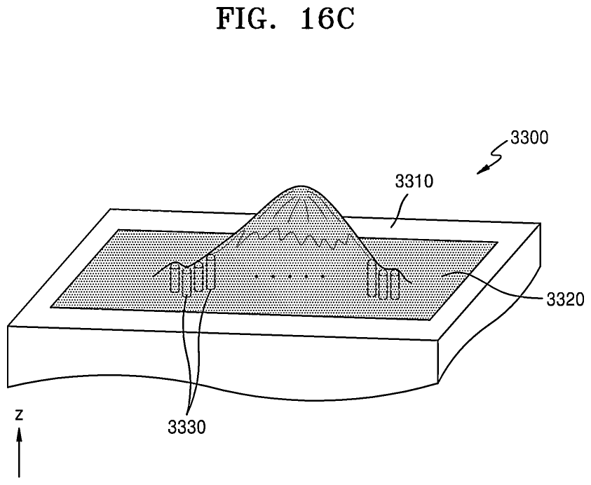

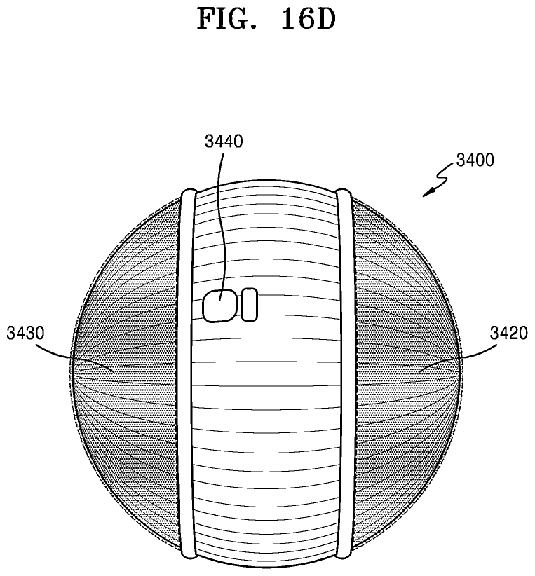

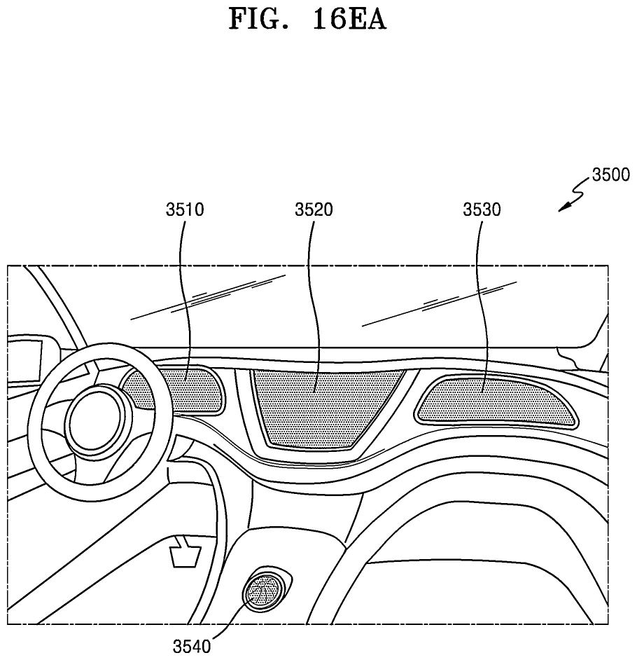

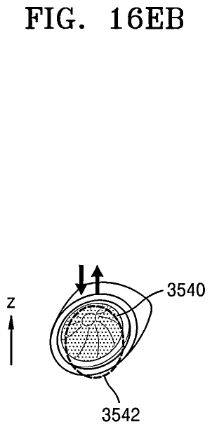

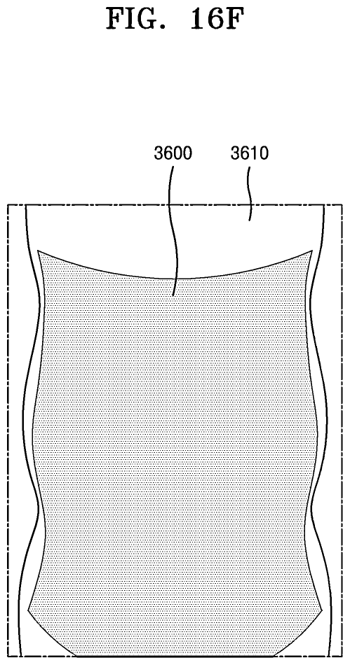

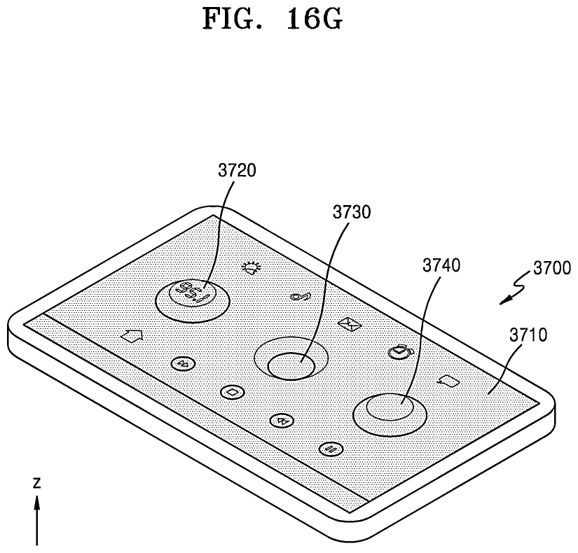

FIGS. 16A to 16G are perspective views schematically illustrating embodiments of an electronic apparatus including the display device.

The display device 1 according to the above-described embodiments may be used in various electronic apparatuses which provide images. The electronic apparatus refers to an apparatus that uses electricity and provides a predetermined image.

Referring to FIG. 16A, the display device in an embodiment may be used in a wearable electronic apparatus 3100 that is wearable on a part of a user's body. The wearable electronic apparatus 3100 may include a body 3110 and a display 3120 provided on the body 3110. The display device in embodiments may be used as the display 3120 of the wearable electronic apparatus 3100. As illustrated in FIG. 16A, the wearable electronic apparatus 3100 may be variously modified. In an embodiment, the wearable electronic apparatus 3100 may be used as a smart watch or a smartphone according to a user's choice.

FIG. 16B illustrates a medical electronic apparatus 3200. In an embodiment, the medical electronic apparatus 3200 may include a body 3210 and a light emitter 3220. The display device in embodiments may be used as the light emitter 3220 of the medical electronic apparatus 3200. The light emitter 3220 may emit light of a predetermined wavelength band (e.g., infrared light, visible light, etc.) to a patient's body. In an embodiment, the body 3210 may include a stretchable fiber material and may have a structure that is wearable on the body of the user who uses the light emitter.

FIG. 16C illustrates an educational electronic apparatus 3300. In an embodiment, the educational electronic apparatus 3300 may include a display 3320 provided in a frame 3310. The display 3320 may use the display devices. The display 3320 may provide images such as a sea with waves, a mountain covered with snow, or a volcano with flowing lava. In this case, the display 3320 may extend in the height direction (e.g., the +z direction) to reflect the height of the waves, the mountain, or the volcano. In some embodiments, a portion of the display 3320 may show the movement of lava in three dimensions by sequentially changing the height in the direction in which the lava flows. The educational electronic apparatus 3300 may include a plurality of pins (or stroke portions, 3330) disposed on the back surface of the display 3320 so that the display 3320 extends in the height direction. As the pins 3330 move in the third direction (e.g., the +z direction or the −z direction), the image displayed on the display 3320 may be implemented to have a three-dimensional height. Although FIG. 16C illustrates the educational electronic apparatus 3300, the use of the educational electronic apparatus 3300 is not limited as long as the educational electronic apparatus 3300 provides predetermined image information.

The electronic apparatuses illustrated in FIGS. 16A to 16C are described as being variable in shape, but the disclosure is not limited thereto. As in the embodiments to be described below, the display device in embodiments may be used in an electronic apparatus in which a part (e.g., a screen) capable of displaying an image is fixed.

FIG. 16D illustrates a robot 3400 as an electronic apparatus. The robot 3400 may recognize movement or objects by a camera 3440 and may display predetermined images to a user on displays 3420 and 3430. In some embodiments, because the display devices in the embodiment may be stretched in various directions, as described above, the display devices may be assembled into a body frame having a hemispherical shape. Accordingly, the robot 3400 may include the hemispherical displays 3420 and 3430.

FIG. 16EA illustrates a vehicle display device 3500 as an electronic apparatus. The vehicle display device 3500 may include a cluster 3510, a center information display (“CID”) 3520, and/or a co-driver display (or a passenger display) 3530. Because the display device in an embodiment may be stretched in various directions, the display device may be used in the cluster 3510, the CID 3520, and/or the co-driver display 3530, regardless of the shape of the internal frame of the vehicle.

Although FIG. 16EA illustrates that the cluster 3510, the CID 3520, and/or the co-driver display 3530 are separated from each other, the disclosure is not limited thereto. In another embodiment, two or more selected from the cluster 3510, the CID 3520, and the co-driver display 3530 may be unitary to each other.

In some embodiments, the vehicle display device 3500 may include a button 3540 which displays a predetermined image. Referring to the enlarged view of FIG. 16EB, the hemispherical button 3540 may include an object 3542 which provides the feeling of using the button while moving in the +z direction or the −z direction, and a display device disposed on the object 3542. In some embodiments, when the object 3542 has a three-dimensionally round surface, the display device may also have a three-dimensionally round surface.

FIG. 16F illustrates that the electronic apparatus in an embodiment is an advertising or exhibition electronic apparatus 3600. In some embodiments, the advertising or exhibition electronic apparatus 3600 may be installed on a fixed structure 3610, such as a wall or a pillar. When the structure 3610 includes an uneven surface as illustrated in FIG. 16F, the advertising or exhibition electronic apparatus 3600 may also be disposed along the uneven surface of the structure 3610. In some embodiments, the advertising or exhibition electronic apparatus 3600 may be installed on the structure 3610 by a heat-shrinkable film or the like.

FIG. 16G illustrates that the electronic apparatus in an embodiment is a controller 3700. The controller 3700 may include an image-type button. In an embodiment, the controller 3700 may include first to third button areas 3720, 3730, and 3740 in which a portion of a display 3710 protrudes in the +z direction or protrudes in the −z direction (or is recessed in the +z direction), for example. In some embodiments, the first and third button areas 3720 and 3740 may protrude in the +z direction, and the second button area 3730 may protrude in the −z direction (or may be recessed in the +z direction).

According to embodiments, a display device that prevents damage due to concentration of stress and expands and contracts in various directions may be provided. These effects are only examples and the scope of the disclosure is not limited by such effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display device in which a display area, and a first area and a second area respectively on opposite sides of the display area are defined, the display device comprising:
a plurality of first island portions arranged in the first area and spaced apart from each other;
a plurality of first bridge portions extending to or connecting the plurality of first island portions adjacent to each other, and spaced apart from each other by a plurality of first openings;
a plurality of second island portions arranged in the second area and spaced apart from each other; and
a plurality of second bridge portions extending to or connecting the plurality of second island portions adjacent to each other, and spaced apart from each other by a plurality of second openings,
wherein the plurality of first bridge portions and the plurality of second bridge portions each have a serpentine shape,
the plurality of first island portions and the plurality of second island portions are arranged symmetrically with respect to a center line between the first area and the second area, and
the plurality of first bridge portions and the plurality of second bridge portions are arranged symmetrically with respect to the center line.

2. The display device of claim 1, wherein the plurality of first island portions comprise a plurality of first driver units,
the plurality of second island portions comprise a plurality of second driver units, and
the plurality of first driver units and the plurality of second driver units are arranged symmetrically with respect to the center line.

3. The display device of claim 1, wherein the plurality of first bridge portions comprise a plurality of first wirings,
the plurality of second bridge portions comprise a plurality of second wirings, and
the plurality of first wirings and the plurality of second wirings are arranged symmetrically with respect to the center line.

4. The display device of claim 1, further comprising:
a third area above the display area and between the first area and the second area;
a plurality of third island portions arranged in the third area and spaced apart from each other; and
a plurality of third bridge portions extending to or connecting the plurality of third island portions adjacent to each other and spaced apart from each other by a plurality of third openings,
wherein the plurality of third bridge portions each have a serpentine shape.

5. The display device of claim 4, wherein the plurality of third bridge portions have a same shape as a shape of the plurality of first bridge portions.

6. The display device of claim 4, wherein the plurality of third bridge portions have a same shape as a shape of the plurality of second bridge portions.

7. The display device of claim 4, further comprising:
a plurality of main island portions arranged in the display area and spaced apart from each other; and
a plurality of main bridge portions extending to the plurality of main island portions adjacent to each other, and spaced apart from each other by a plurality of main openings,
wherein the plurality of main bridge portions each have a serpentine shape.

8. The display device of claim 7, wherein the plurality of main island portions and the plurality of first island portions are arranged in a matrix form, and
the plurality of main island portions arranged in one row correspond to the plurality of first island portions arranged in a plurality of rows.

9. The display device of claim 7, further comprising:
a fourth area between the first area and the display area; and
a plurality of fourth bridge portions arranged in the fourth area and extending to the plurality of first island portions and the plurality of main island portions adjacent to each other.

10. The display device of claim 7, wherein the display area comprises a first display area and a second display area with the center line therebetween,
the plurality of main island portions of the first display area and the plurality of main island portions of the second display area are arranged symmetrically with respect to the center line, and
the plurality of main bridge portions of the first display area and the plurality of main bridge portions of the second display area are arranged symmetrically with respect to the center line.

11. The display device of claim 10, wherein the third area comprises a first sub-area and a second sub-area with the center line therebetween,
the plurality of third island portions of the first sub-area and the plurality of third island portions of the second sub-area are arranged symmetrically with respect to the center line, and
the plurality of third bridge portions of the first sub-area and the plurality of third bridge portions of the second sub-area are arranged symmetrically with respect to the center line.

12. The display device of claim 11, further comprising:
a first central area between the first display area and the second display area; and
a second central area between the first sub-area and the second sub-area,
wherein the center line passes through the first central area and the second central area.

13. The display device of claim 12, wherein a plurality of openings corresponding to the first central area and the second central area are defined in the first central area and the second central area.

14. The display device of claim 12, further comprising a plurality of first central bridge portions arranged in the first central area and extending to the plurality of main island portions of the first display area and the plurality of main island portions of the second display area, the plurality of main island portions of the first display area and the plurality of main island portions of the second display area being adjacent to each other.

15. The display device of claim 14, further comprising a plurality of second central bridge portions arranged in the second central area and extending to the plurality of third island portions of the first sub-area and the plurality of third island portions of the second sub-area, the plurality of third island portions of the first sub-area and the plurality of third island portions of the second sub-area being adjacent to each other.

16. The display device of claim 14, wherein an opening corresponding to the second central area is defined in the second central area.

17. The display device of claim 12, further comprising a plurality of second central bridge portions arranged in the second central area and extending to the plurality of third island portions of the first sub-area and the plurality of third island portions of the second sub-area, the plurality of third island portions of the first sub-area and the plurality of third island portions of the second sub-area being adjacent to each other,
wherein an opening corresponding to the first central area is defined in the first central area.

18. The display device of claim 15, wherein a width of each of the plurality of second central bridge portions is greater than a width of each of the plurality of first central bridge portions.

19. The display device of claim 14, wherein the plurality of first central bridge portions each have a serpentine shape.

20. The display device of claim 14, wherein the plurality of first central bridge portions each have a straight-line shape.
